(19) United States
(12) Patent Application Publication
(10) Pub. No.: US 2026/0101673 A1
(43) Pub. Date: Apr. 9, 2026

(54) DEVICE COMPRISING AN ACOUSTIC LAYER AND VIA INTERCONNECT

(71) Applicant: RF360 Singapore Pte. Ltd., Munich (DE)

(72) Inventors: Sebastian BRUNNER, Graz (AT); Thomas METZGER, Munich (DE); Maximilian SCHIEK, Puchheim (DE); Willi AIGNER, Moosinning (DE); Ralph DURNER, München (DE); Christian CERANSKI, München (DE); Marc ESQUIUS MOROTE, Munich (DE); Horst DROESCHER, Frauental an der Laßnitz (AT)

(21) Appl. No.: 18/911,043

(22) Filed: Oct. 9, 2024

(51) Int. Cl. H10N 30/87; H03H 9/17; H10N 30/853; H10N 30/88

(52) U.S. Cl. CPC H10N 30/874; H10N 30/853; H10N 30/88; H03H 9/175

(57) ABSTRACT

A device comprising a lid layer; an acoustic layer coupled to the lid layer, wherein the acoustic layer comprises: a piezoelectric layer; a dielectric layer; at least one material layer located in the dielectric layer; and a plurality of interconnects coupled to the piezoelectric layer; a cavity located between the lid layer and the piezoelectric layer; a substrate coupled to the dielectric layer of the acoustic layer; and at least one via interconnect coupled to the piezoelectric layer through the plurality of interconnects, wherein the at least one via interconnect extends through the dielectric layer and the substrate.

### FIELD

Various features relate to integrated devices and devices with acoustic layers.

### BACKGROUND

A package may include a substrate, integrated devices and/or other components. These components, which may include acoustic devices, are coupled together to provide a package that may perform various electrical functions. There is an ongoing need to provide better performing packages that include components with increased and/or improved capabilities. Moreover, there is also an ongoing need to reduce and/or minimize the overall size of these components and/or these packages.

### SUMMARY

Various features relate to integrated devices and devices with acoustic layers.

One example provides a device comprising a lid layer; an acoustic layer coupled to the lid layer, wherein the acoustic layer comprises: a piezoelectric layer; a dielectric layer; at least one material layer located in the dielectric layer; and a plurality of interconnects coupled to the piezoelectric layer; a cavity located between the lid layer and the piezoelectric layer; a substrate coupled to the dielectric layer of the acoustic layer; and at least one via interconnect coupled to the piezoelectric layer through the plurality of interconnects, wherein the at least one via interconnect extends through the dielectric layer and the substrate.

Another example provide a method for fabricating an acoustic device. The method provides a lid layer. The method couples an acoustic layer to the lid layer. The acoustic layer comprises a piezoelectric layer; a dielectric layer; at least one material layer located in the dielectric layer; and a plurality of interconnects coupled to the piezoelectric layer; wherein the acoustic layer is coupled to the lid layer such that a cavity is located between the lid layer and the piezoelectric layer; coupling a substrate to the dielectric layer of the acoustic layer; and forming at least one via interconnect that is to the piezoelectric layer through the plurality of interconnects, wherein the at least one via interconnect extends through the dielectric layer and the substrate.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a device comprising an acoustic layer, an acoustic mirror portion and at least one via interconnect.

FIG. 2 illustrates an exemplary cross sectional profile view of a device comprising an acoustic layer, an acoustic mirror portion and at least one via interconnect.

FIG. 3 illustrates an exemplary cross sectional profile view of a device comprising an acoustic layer, an acoustic mirror portion and at least one via interconnect.

FIG. 4 illustrates an exemplary cross sectional profile view of a device comprising an acoustic layer, an acoustic mirror portion and at least one via interconnect.

FIGS. 5A-5H illustrate an exemplary sequence for fabricating a device comprising an acoustic layer, an acoustic mirror portion and at least one via interconnect.

FIG. 6 illustrate an exemplary flow diagram of a method for fabricating a device comprising an acoustic layer, an acoustic mirror portion and at least one via interconnect.

FIGS. 7A-7C illustrate an exemplary sequence for fabricating a lid layer.

FIGS. 8A-8D illustrate an exemplary sequence for fabricating an acoustic layer.

FIGS. 9A-9D illustrate an exemplary sequence for fabricating a substrate.

FIG. 10 illustrates an exemplary cross sectional profile view of a device comprising an acoustic layer, an acoustic mirror portion and at least one via interconnect.

FIGS. 11A-11H illustrate an exemplary sequence for fabricating a device comprising an acoustic layer, an acoustic mirror portion and at least one via interconnect.

FIG. 12 illustrate an exemplary flow diagram of a method for fabricating a device comprising an acoustic layer, an acoustic mirror portion and at least one via interconnect.

FIG. 13 illustrates an exemplary cross sectional profile view of a device comprising an acoustic layer, an acoustic mirror portion and at least one via interconnect.

FIG. 14 illustrates an exemplary cross sectional profile view of a device comprising an acoustic layer, an acoustic mirror portion and at least one via interconnect.

FIG. 15 illustrates an exemplary cross sectional profile view of a device comprising an acoustic layer, an acoustic mirror portion and at least one via interconnect.

FIG. 16 illustrates an exemplary cross sectional profile view of a device comprising an acoustic layer, an acoustic mirror portion and at least one via interconnect.

FIG. 17 illustrates an exemplary cross sectional profile view of a device comprising an acoustic layer, an acoustic mirror portion and at least one via interconnect.

FIG. 18 illustrates an exemplary cross sectional profile view of a package comprising several devices that each comprise an acoustic layer, an acoustic mirror portion and at least one via interconnect.

FIG. 19 illustrates an exemplary cross sectional profile view of a package comprising several devices that each comprise an acoustic layer, an acoustic mirror portion and at least one via interconnect.

FIG. 20 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a device comprising a lid layer; an acoustic layer coupled to the lid layer, wherein the acoustic layer comprises: a piezoelectric layer; a dielectric layer; at least one material layer located in the dielectric layer; and a plurality of interconnects coupled to the piezoelectric layer; a cavity located between the lid layer and the piezoelectric layer; a substrate coupled to the dielectric layer of the acoustic layer; and at least one via interconnect coupled to the piezoelectric layer through the plurality of interconnects, wherein the at least one via interconnect extends through the dielectric layer and the substrate. The use of the at least one via interconnect helps provide an electrical and/or thermal path for to and/or from the piezoelectric layer.

### Exemplary Device Comprising an Acoustic Layer and at Least One Via Interconnect

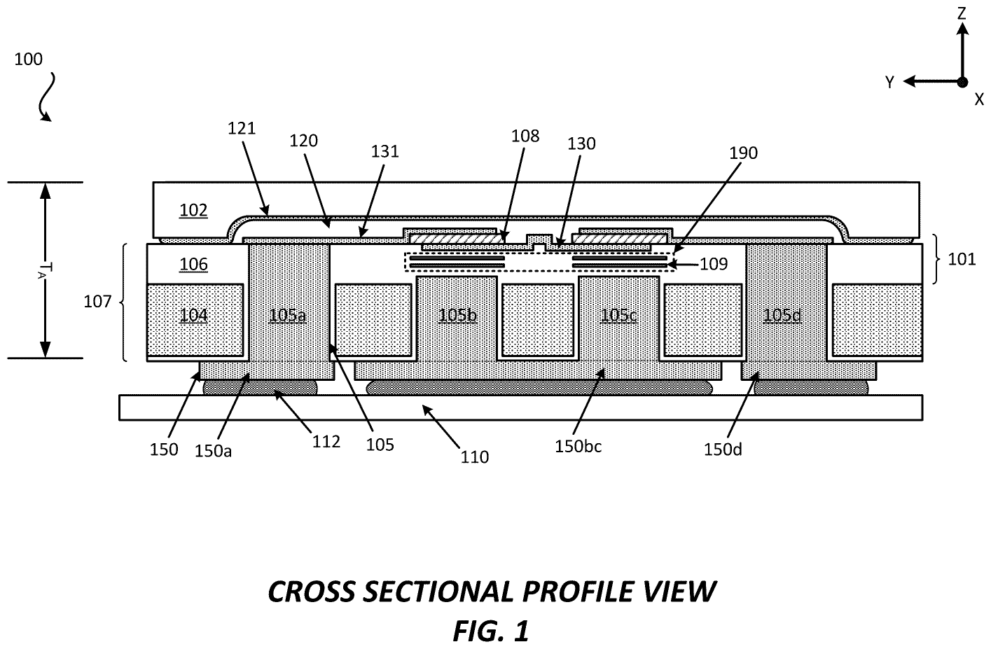

FIG. 1 illustrates a cross sectional profile view of a device 100 that includes an acoustic layer and at least one via interconnect. The device 100 may be an acoustic device (e.g., acoustic wave device). The device 100 may be an integrated device configured as an acoustic wave device. The device 100 may be an integrated acoustic wave device. An example of an acoustic wave device may include a bulk acoustic wave (BAW) resonator. The device 100 may be configured to operate as an acoustic filter. The device 100 is coupled to a substrate 110 through a plurality of solder interconnects 112. The substrate 110 may be an interposer. The substrate 110 may be a laminated substrate (e.g., coreless substrate, cored substrate). The substrate 110 may be a package substrate. As will be further described below, the device 100 may be coupled to the substrate 110 through hybrid bonding.

The device 100 includes a lid layer 102 and a device base 107. The device base 107 may include the acoustic layer 101, the substrate 104, at least one dielectric layer 106, a plurality of via interconnects 105, and a plurality of metallization interconnects 150. The acoustic layer 101 may include the at least one dielectric layer 106, a piezoelectric layer 108, a plurality of interconnects 130, a plurality of interconnects 131, and at least one material layer 109. The plurality of interconnects 130 and/or the plurality of interconnects 131 may be configured as electrodes.

The at least one material layer 109 and a portion of the at least one dielectric layer 106 may define an acoustic mirror portion 190. The acoustic mirror portion 190 may be configured as a Bragg mirror, to help reduce the loss of acoustic energy. For example, the acoustic mirror portion 190 may be configured to reflect acoustic energy back towards the piezoelectric layer 108. The at least one dielectric layer 106 includes a first acoustic impedance (e.g., first acoustic impedance value, low acoustic impedance value) and the at least one material layer 109 includes a second acoustic impedance (e.g., second acoustic impedance value, high acoustic impedance value) that is different from the first acoustic impedance. For example, the at least one material layer 109 may have a higher acoustic impedance than the acoustic impedance of the at least one dielectric layer 106. In some implementations, the at least one dielectric layer 106 may include silicon dioxide (SiO₂). In some implementations, the at least one material layer 109 may include tungsten. The at least one material layer 109 may include a different material from the plurality of interconnects 130, the plurality of interconnects 131 and/or the plurality of via interconnects 105. The at least one material layer 109 may be an acoustic mirror layer. The at least one material layer 109 may include multiple material layers (e.g., multiple acoustic mirror layers) that vertically overlap with the piezoelectric layer 108. Different implementations may have different numbers of material layers. In some implementations, the at least one material layer 109 may include several vertical stacks of acoustic mirror layers. The at least one material layer 109 may not be electrically coupled to the piezoelectric layer 108, the plurality of interconnects 130, the plurality of interconnects 131 and/or the plurality of via interconnects 105.

Some of via interconnects from the plurality of via interconnects are coupled to the plurality of interconnects 130 and/or the plurality of interconnects 131. Some of via interconnects from the plurality of via interconnects 105 may extend through the at least one dielectric layer 106 and/or the substrate 104. The substrate 104 may include silicon (Si). Some of via interconnects from the plurality of via interconnects 105 may extend through the substrate 104. Some of via interconnects from the plurality of via interconnects 105 may vertically overlap with the acoustic mirror portion 190. Some of the via interconnects from the plurality of via interconnects 105 may vertically overlap with the piezoelectric layer 108. The plurality of via interconnects 105 may include a via interconnect 105a, a via interconnect 105b, a via interconnect 105c and a via interconnect 105d. The via interconnect 105a is coupled to the plurality of interconnects 131. The via interconnect 105d is coupled to the plurality of interconnects 131. The via interconnect 105a extends through the substrate 104 and the at least one dielectric layer 106. The via interconnect 105d extends through the substrate 104 and the at least one dielectric layer 106. The via interconnect 105d is coupled to the plurality of interconnects 131. In some implementations, the via interconnect 105a and/or the via interconnect 105d may be configured to be electrically coupled to the plurality of interconnects 130, the plurality of interconnects 131 and/or the piezoelectric layer 108. Thus, the via interconnect 105a and/or the via interconnect 105d may be configured to provide an electrical path through the device base 107 of the device 100.

The via interconnect 105b extends through the substrate 104 and part of the at least one dielectric layer 106. The via interconnect 105b vertically overlaps with at least part of the acoustic mirror portion 190. The via interconnect 105b vertically overlaps with at least a portion of the piezoelectric layer 108. The via interconnect 105c extends through the substrate 104 and part of the at least one dielectric layer 106. The via interconnect 105c vertically overlaps with at least part of the acoustic mirror portion 190. The via interconnect 105c vertically overlaps with at least a portion of the piezoelectric layer 108. In some implementations, the via interconnect 105b and/or the via interconnect 105c may be free of any electrical connection with the piezoelectric layer 108. In some implementations, the via interconnect 105b and/or the via interconnect 105c may be configured to dissipate heat away from the piezoelectric layer 108. The via interconnect 105b and/or the via interconnect 105c may be examples of thermal via interconnects.

The plurality of interconnects 130, the plurality of interconnects 131 and/or the piezoelectric layer 108 are located on a first side of the device base 107. The plurality of interconnects 130, the plurality of interconnects 131 and/or the piezoelectric layer 108 may be located on a first surface of the at least one dielectric layer 106. The acoustic mirror portion 190 may be located between (i) the piezoelectric layer 108 and (ii) the via interconnect 105b and/or the via interconnect 105c. The plurality of metallization interconnects 150 are coupled to the plurality of via interconnects 105. The plurality of metallization interconnects 150 may be located in and/or on a second side of the device base 107. The second side of the device base 107 may be opposite to the first side of the device base 107. The plurality of metallization interconnects 150 are coupled to the plurality of solder interconnects 112. The plurality of metallization interconnects 150 may include a plurality of pad interconnects. The plurality of metallization interconnects 150 include a metallization interconnect 150a, a metallization interconnect 150bc and a metallization interconnect 150d. The metallization interconnect 150a is coupled to the via interconnect 105a. The metallization interconnect 150bc is coupled to the via interconnect 105b and the via interconnect 105c. The metallization interconnect 150bc may be one pad interconnect for the via interconnect 105b and the via interconnect 105c. The increase in lateral size of the metallization interconnect 150bc helps dissipate heat away from the piezoelectric layer 108. The metallization interconnect 150d is coupled to the via interconnect 105d.

A metal layer 121 is formed and/or coupled to a surface of the lid layer 102. The lid layer 102 may include glass, silicon, fused silica, ceramic, or a combination thereof. The lid layer 102 is coupled to the device base 107 through the metal layer 121. The metal layer 121 may be coupled to a metal layer (not shown) of the device base 107. The metal layer 121 helps provide a hermetic seal between the lid layer 102 and the device base 107. The metal layer 121 may also help provide shielding (e.g., electromagnetic interference shielding) for the acoustic layer 101. A cavity 120 is located between the lid layer 102 and the piezoelectric layer 108. The cavity 120 may be formed in the lid layer 102. The cavity 120 may be located between (i) the lid layer 102 and (ii) the plurality of interconnects 130 and/or the plurality of interconnects 131. A cavity may be at least one region that is free of a solid material. A cavity may be occupied by a gas (e.g., air).

FIG. 1 illustrates an example of a compact and efficient acoustic wave resonator that includes via interconnects in the device base 107. In some implementations, the combined thickness (T_{A}) of the lid layer 102 and the device base 107 may be 200 micrometers or less. The plurality of via interconnects 105 are configured to provide at least one electrical path between the piezoelectric layer 108 and the substrate 110. Thus, the device base 107 provides functional capabilities for the device 100. For example, some of the via interconnects from the plurality of via interconnects 105 provide additional functionality for the device. Moreover, the presence of the acoustic mirror portion 190 helps improve the performance of the acoustic wave resonator by reducing loss of the acoustic energy and/or redirecting acoustic energy towards the piezoelectric layer 108. It is noted that the components shown in the disclosure may or may not be to scale. For example, in some implementations, the acoustic mirror portion 190 may have a thickness in a range of about 2 micrometers, and the plurality of via interconnects 105 may have a width in a range of about 5-15 micrometers. FIG. 1 illustrates an example of a device that includes via interconnects and an acoustic mirror portion, to provide an improved and compact acoustic wave resonator. As will be further described below in the disclosure, other devices may have other configurations and/or designs.

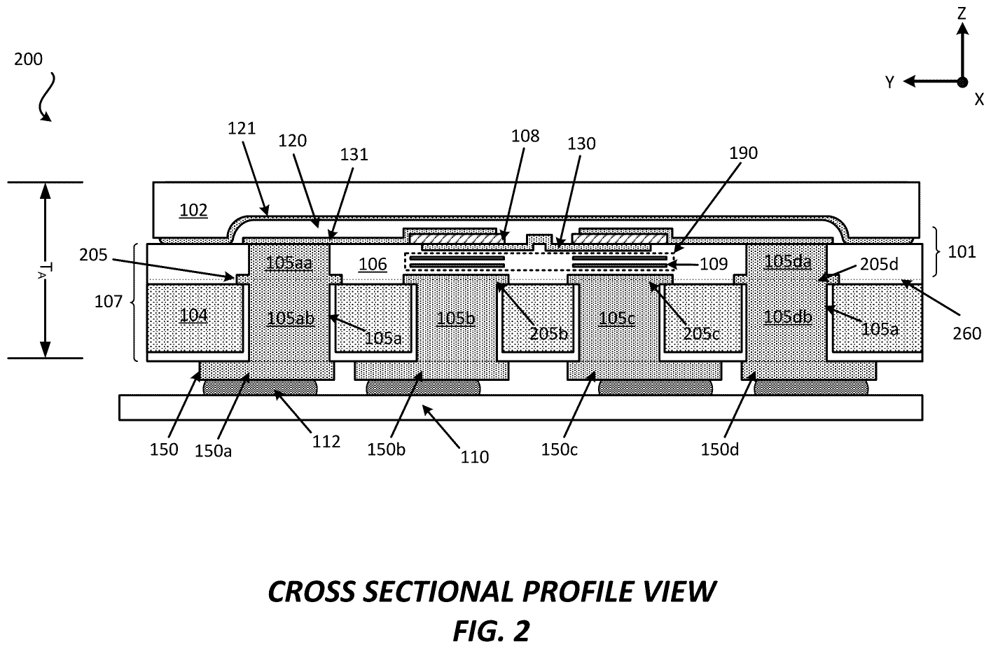

FIG. 2 illustrates a cross sectional profile view of a device 200 that includes an acoustic layer, an acoustic mirror portion and at least one via interconnect. The device 200 may be similar to the device 100 of FIG. 1, and may include similar and/or the same components as described for the device 100. Thus, the description of the device 100 of FIG. 1 may also be applicable to the device 200. The device 200 includes a plurality of via interconnects 105 that have different designs and/or configurations. The device 200 may be an acoustic wave device. The device 200 may be an integrated device configured as an acoustic wave device. The device 200 may be an integrated acoustic wave device. The device 200 may be configured to operate as an acoustic filter.

The device 200 includes a plurality of via interconnects 105, a plurality of pad interconnects 205 and a plurality of metallization interconnects 150. The plurality of via interconnects 105 are coupled to the plurality of interconnects 130, the plurality of interconnects 131 and/or the piezoelectric layer 108. The plurality of via interconnects 105 includes a via interconnect 105a, a via interconnect 105b, a via interconnect 105c and a via interconnect 105d. The via interconnect 105a is coupled to the plurality of interconnects 130, the plurality of interconnects 131 and/or the piezoelectric layer 108. The via interconnect 105d is coupled to the plurality of interconnects 130, the plurality of interconnects 131 and/or the piezoelectric layer 108. The plurality of pad interconnects 205 may include a pad interconnect 205a, a pad interconnect 205b, a pad interconnect 205c and a pad interconnect 205d. The plurality of pad interconnects 205 may be located in the at least one dielectric layer 106.

The via interconnect 105a may include a via interconnect 105aa, a pad interconnect 205a and a via interconnect 105ab. The pad interconnect 205a may be located between the via interconnect 105aa and the via interconnect 105ab. The pad interconnect 205a may have a width that is greater than a width of the via interconnect 105aa and/or a width of the via interconnect 105ab. The via interconnect 105aa may be a first via interconnect portion of the via interconnect 105a. The via interconnect 105ab may be a second via interconnect portion of the via interconnect 105a. The via interconnect 105aa may extend through the at least one dielectric layer 106. The pad interconnect 205a may be located in the at least one dielectric layer 106. The via interconnect 105ab may extend through the substrate 104.

The via interconnect 105d may include a via interconnect 105da, a pad interconnect 205d and a via interconnect 105db. The pad interconnect 205d may be located between the via interconnect 105da and the via interconnect 105db. The pad interconnect 205d may have a width that is greater than a width of the via interconnect 105da and/or a width of the via interconnect 105db. The via interconnect 105da may be a first via interconnect portion of the via interconnect 105d. The via interconnect 105db may be a second via interconnect portion of the via interconnect 105d. The via interconnect 105da may extend through the at least one dielectric layer 106. The pad interconnect 205d may be located in the at least one dielectric layer 106. The via interconnect 105db may extend through the substrate 104.

The plurality of metallization interconnects 150 may include a plurality of pad interconnects. The plurality of metallization interconnects 150 may include a metallization interconnect 150a, a metallization interconnect 150b, a metallization interconnect 150c and a metallization interconnect 150d. The metallization interconnect 150a is coupled to the via interconnect 105ab. The metallization interconnect 150b is coupled to the via interconnect 105b. The metallization interconnect 150c is coupled to the via interconnect 105c. The metallization interconnect 150d is coupled to the via interconnect 105db.

FIG. 2 illustrates a bond interface 260. The bond interface 260 may be a conceptual representation of where different portions of the device base 107 may be coupled together to form the device base 107. The bond interface 260 may not be visible nor detectable in the device base 107. For example, the dielectric layer 106 above the bond interface 260 may not be separate from the dielectric layer 106 below the bond interface 260. The dielectric layer 106 above the bond interface 260 may be continuous and/or contiguous to the dielectric layer 106 below the bond interface 260. Similarly, the portions of the plurality of pad interconnects 205 above the bond interface 260 may not be separate from the portions of the plurality of pad interconnects 205 below the bond interface 260. The portions of the plurality of pad interconnects 205 above the bond interface 260 may be continuous and/or contiguous to the portions of the plurality of pad interconnects 205 below the bond interface 260.

The plurality of pad interconnects 205 may be a byproduct of the process used to fabricate the device. Different implementations may have pad interconnects from the plurality of pad interconnects 205, with different shapes and/or sizes. In some implementations, the plurality of via interconnects 105, the plurality of pad interconnects 205, and/or the plurality of metallization interconnects 150 may include one or more seed layers. Examples of devices with interconnects with seed layers and/or other interconnects are described below.

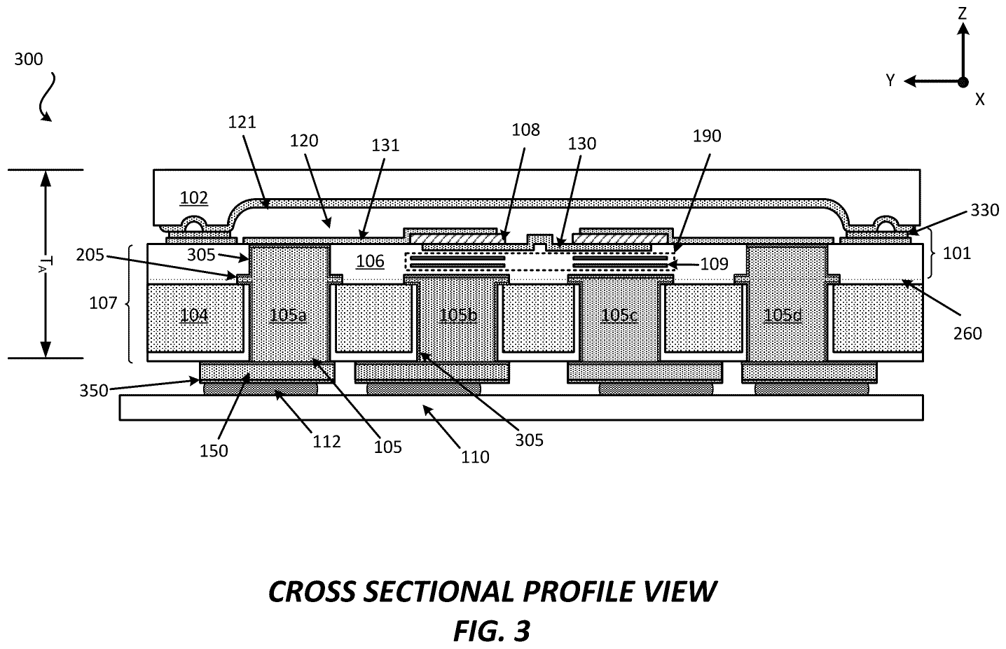

FIG. 3 illustrates a cross sectional profile view of a device 300 that includes an acoustic layer, an acoustic mirror portion and at least one via interconnect. The device 300 may be similar to the device 100 of FIG. 1 and/or the device 200 of FIG. 2, and may include similar and/or the same components as described for the device 100 and/or the device 200. Thus, the description of the device 100 of FIG. 1 and/or the description of the device 200 of FIG. 2 may also be applicable to the device 300. The device 300 includes a plurality of interconnects that comprise one or more barrier and seed layers. The barrier (diffusion) and seed layer(s) may be considered part of the plurality of interconnects. The device 300 may be an acoustic device (e.g., acoustic wave device). The device 300 may be an integrated device configured as an acoustic wave device. The device 300 may be an integrated acoustic wave device.

The device 300 include a plurality of via interconnects 105. The device 300 may include a plurality of pad interconnects 205. The plurality of via interconnects 105 may include a seed layer 305. The plurality of pad interconnects 205 may include a seed layer 305. The seed layer 305 may include one or more seed layers. The seed layer 305 may include titanium and/or copper. A metal layer 350 may be coupled to the plurality of metallization interconnects 150. The metal layer 350 may include a different material from the plurality of metallization interconnects 150. The seed layer 305 may be coupled to the plurality of interconnects 131. In some implementations, the seed layer 305 may not be distinguishable from the plurality of via interconnects 105, the plurality of pad interconnects 205 and/or the plurality of metallization interconnects 150. The seed layer 305 may be located on the side wall of the plurality of interconnects. In some implementations, there may be more than one metal layer 350. Each additional metal layer may include different materials.

The lid layer 102 may be coupled to the device base 107 through the metal layer 121, the metal layer 330 and a metal layer of the device base 107, and may help provide a hermetic seal between the lid layer 102 and the device base 107. The metal layer 121, the metal layer 330 and the metal layer of the device base 107 may include the same materials and/or different materials.

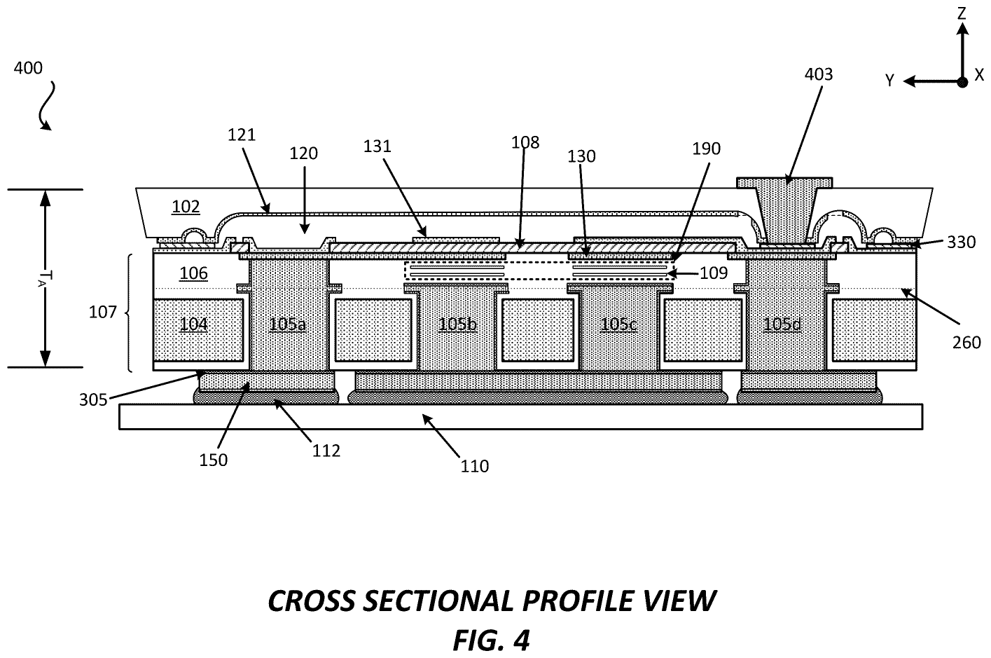

FIG. 4 illustrates a cross sectional profile view of a device 400 that includes an acoustic layer, an acoustic mirror portion and at least one via interconnect. The device 400 may be similar to the device 100 of FIG. 1, the device 200 of FIG. 2 and/or the device 300 of FIG. 3, and may include similar and/or the same components as described for the device 100, the device 200 and/or the device 300. Thus, the description of the device 100 of FIG. 1, the description of the device 200 of FIG. 2, and/or the description of the device 300 of FIG. 3 may also be applicable to the device 400. As shown in FIG. 4, the device 400 includes a plurality of interconnects 403 in the lid layer 102. The plurality of interconnects 403 may include via interconnects and/or pad interconnects. The plurality of interconnects 403 may extend through the lid layer 102. The plurality of interconnects 403 may be coupled to the plurality of interconnects 130 and/or the plurality of interconnects 131. The plurality of interconnects 403 may be configured to provide at least one electrical and/or thermal path for the device 400. In some implementations, a first electrical and/or thermal path may extend through the via interconnect 105a. In some implementations, a second electrical and/or thermal path may extend through the via interconnect from the plurality of interconnects 403. In some implementations, an electrical and/or thermal path may extend through a via interconnect from the plurality of via interconnects 403, an interconnect from the plurality of interconnects 131, a via interconnect 105d and a metallization interconnect from the plurality of metallization interconnects 150. Thus, an electrical and/or thermal path may extend through the lid layer 102. FIG. 4 illustrates an example of a device with additional interconnects to provide additional functionality for the device.

The device 400 may be coupled to other components through the plurality of interconnects 403. For example, a substrate (e.g., laminated substrate) may be coupled to the plurality of interconnects 403 through solder interconnects. In another example, an integrated device may be coupled to the plurality of interconnects 403 through solder interconnects.

A plurality of metallization interconnects (e.g., 150) may include a plurality of redistribution interconnects. A redistribution interconnect may include portions that have a U-shape or V-shape. The terms “U-shape” and “V-shape” shall be interchangeable. The terms “U-shape” and “V-shape” may refer to the side profile shape of the interconnects, metallization interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). In some implementations, a process for fabricating redistribution interconnects may form the U-shape interconnect (or the V-shape interconnect).

As mentioned above, a device may be an integrated device. In some implementations, a device may be implemented to be electrically coupled to an integrated device. An integrated device may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one or more of integrated devices described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package may be implemented in a radio frequency (RF) package. The RF package may be a radio frequency front end (RFFE) package. A package may be configured to provide Wireless Fidelity (WiFi) communication and/or cellular communication (e.g., 2G, 3G, 4G, 5G, 6G). The packages may be configured to support Global System for Mobile (GSM) Communications, Universal Mobile Telecommunications System (UMTS), and/or Long-Term Evolution (LTE). The packages may be configured to transmit and receive signals having different frequencies and/or communication protocols.

### Exemplary Sequence for Fabricating a Device Comprising an Acoustic Layer and at Least One Via Interconnect

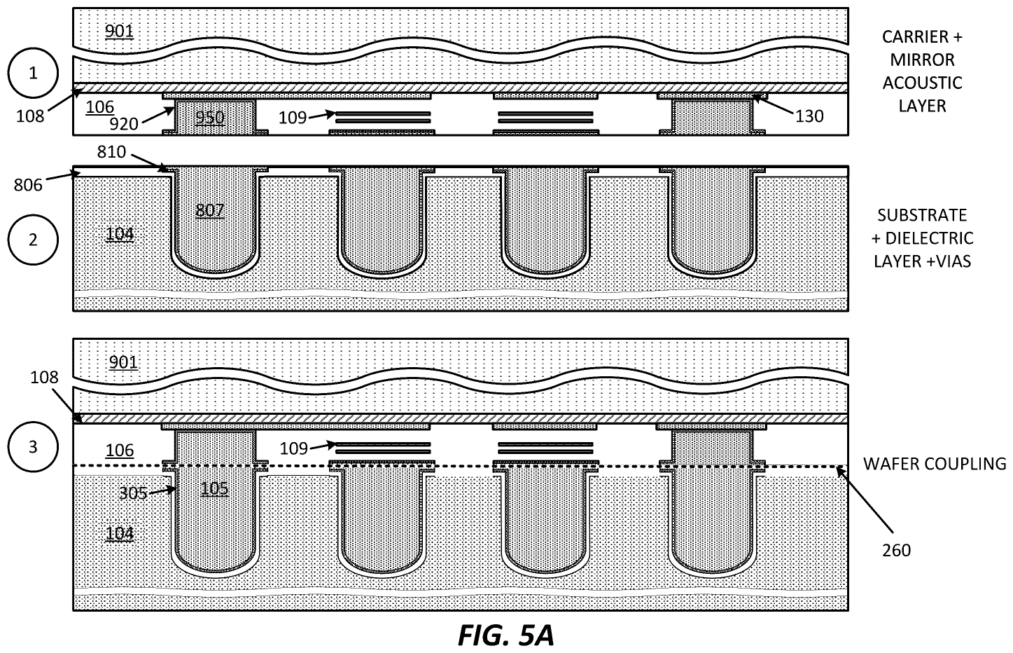

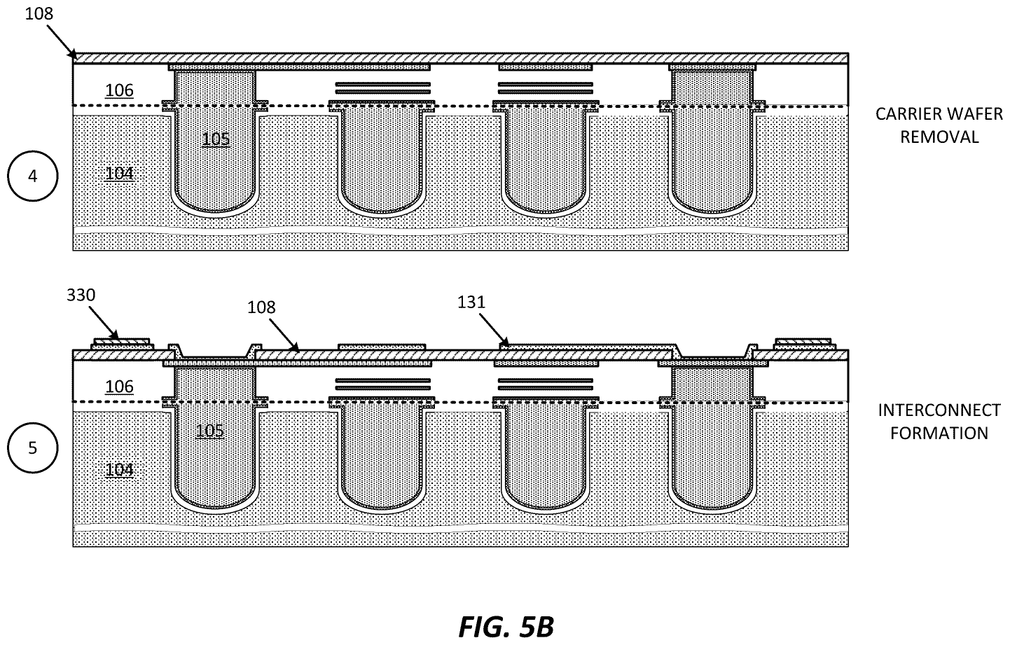

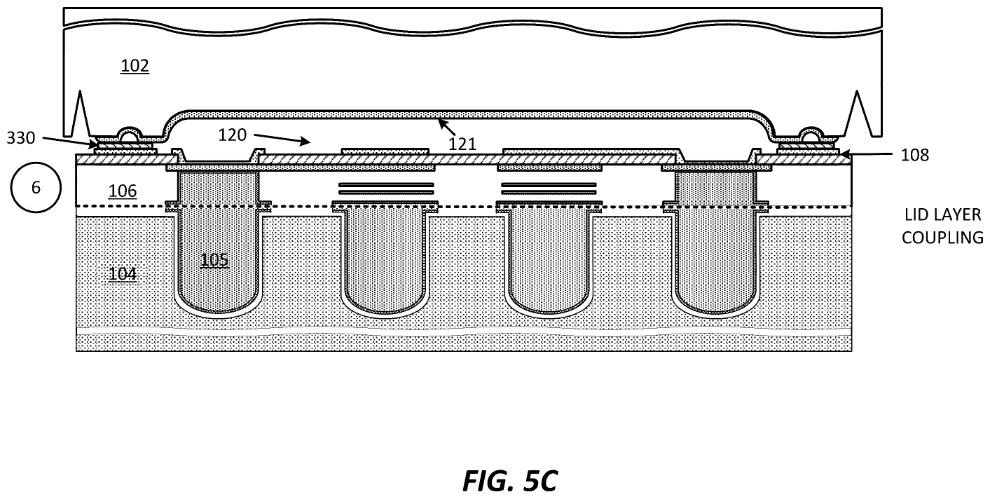

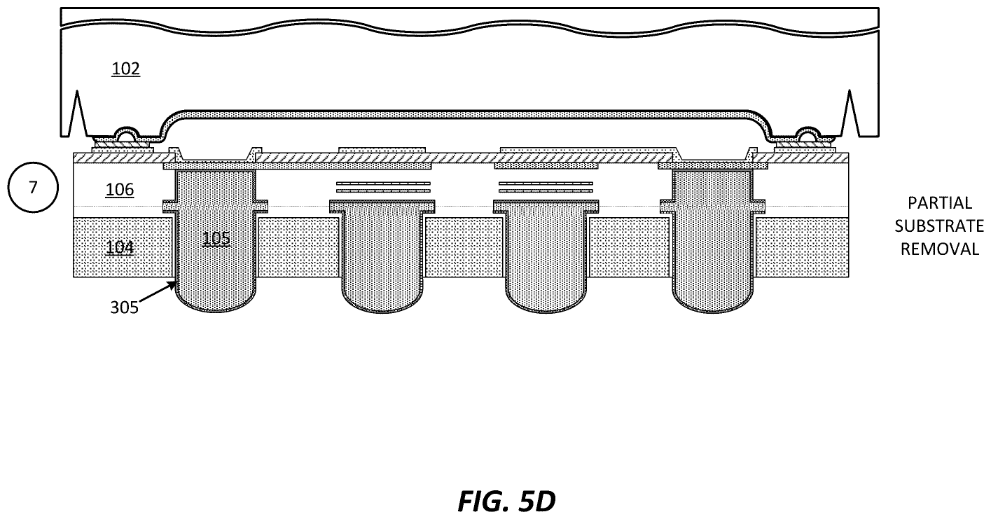

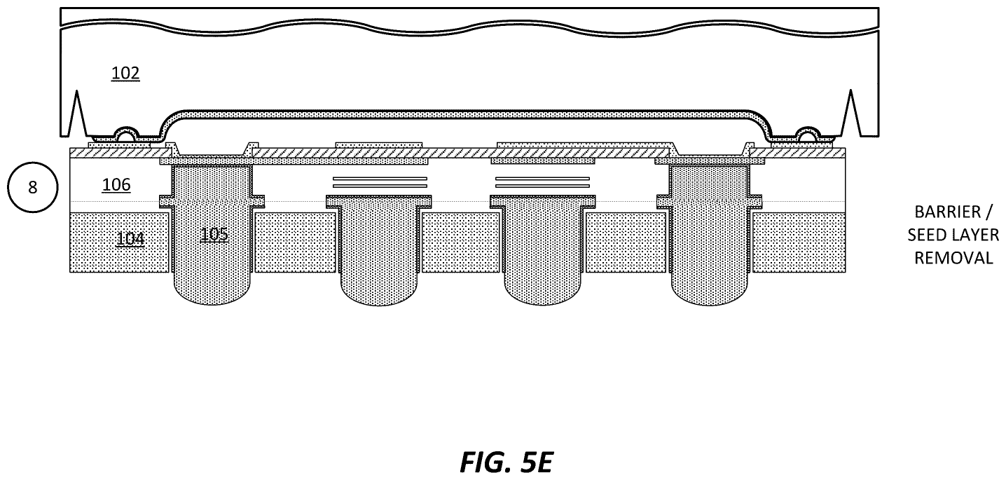

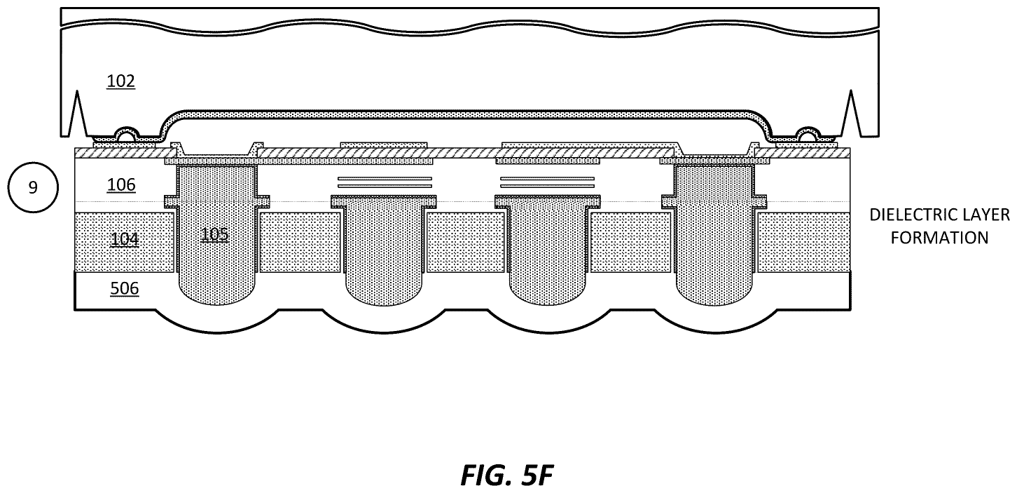

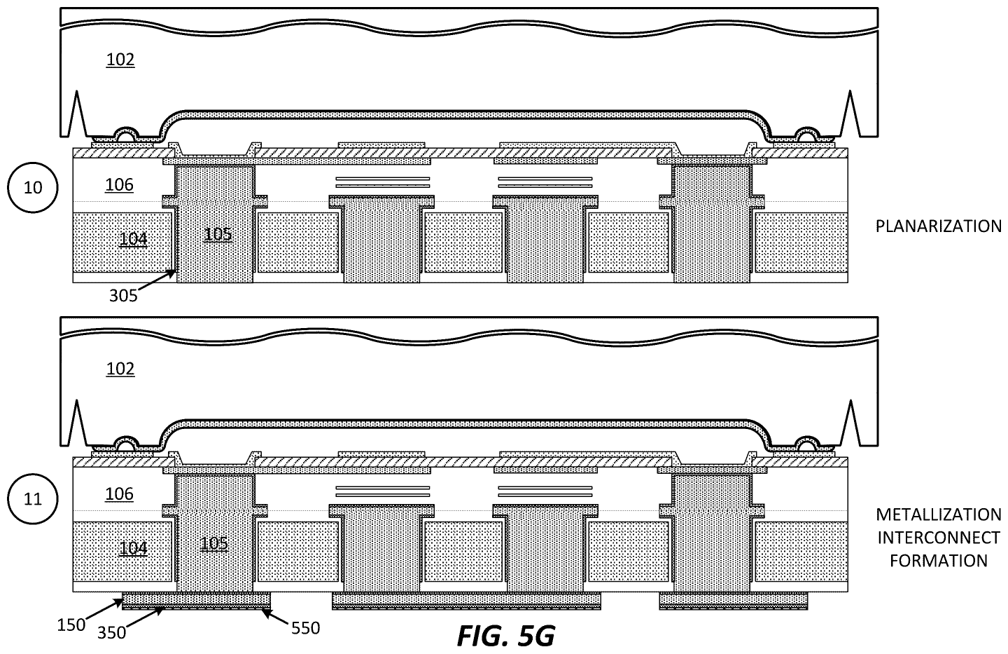

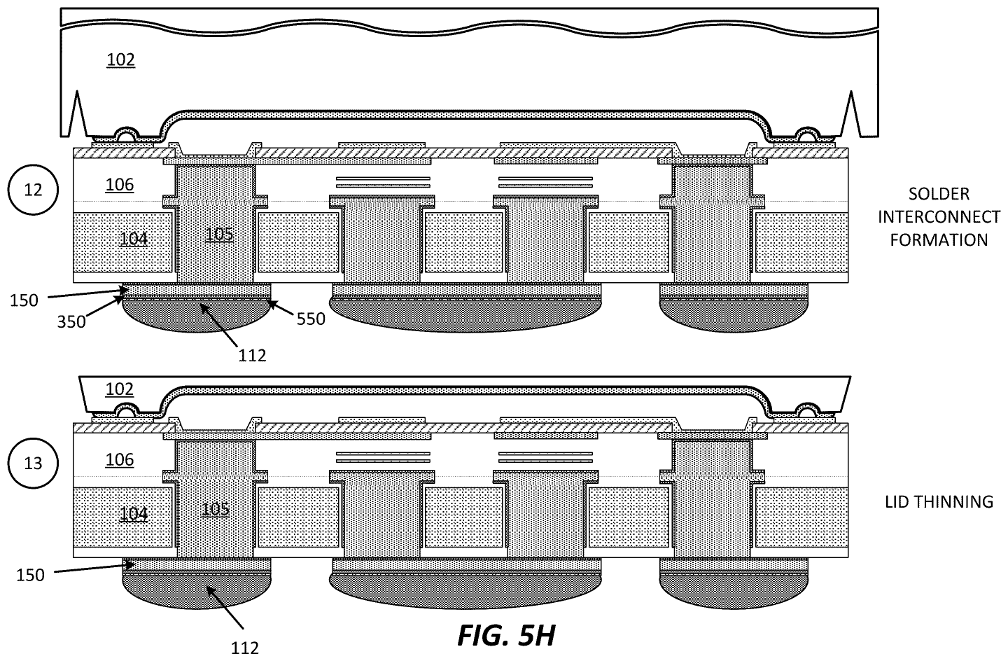

In some implementations, fabricating a device includes several processes. FIGS. 5A-5H illustrate an exemplary sequence for providing or fabricating a device comprising an acoustic layer and at least one via interconnect. In some implementations, the sequence of FIGS. 5A-5H may be used to provide or fabricate the device 300. However, the process of FIGS. 5A-5H may be used to fabricate any of the devices described in the disclosure.

It should be noted that the sequence of FIGS. 5A-5H may combine one or more stages in order to simplify and/or clarify the sequence for providing or fabricating a device. In some implementations, the order of the processes may be changed or modified. In some implementations, one or more of processes may be replaced or substituted without departing from the scope of the disclosure.

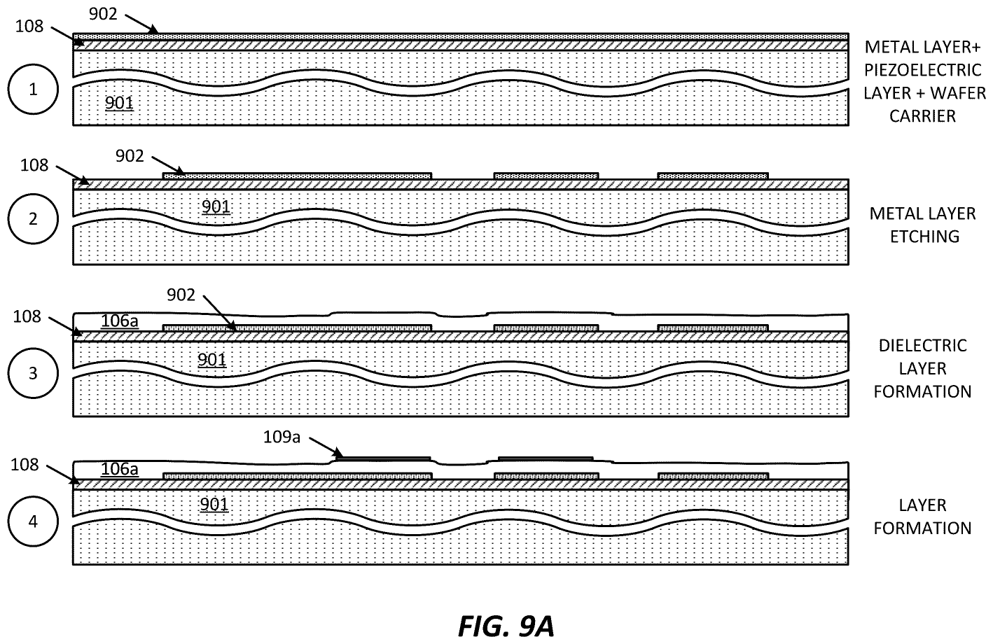

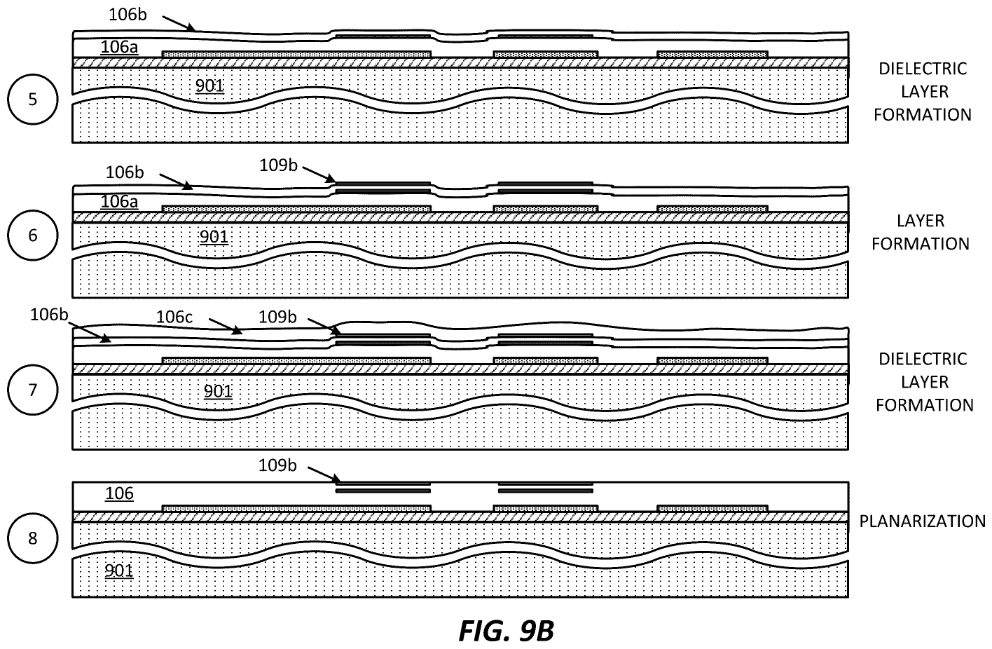

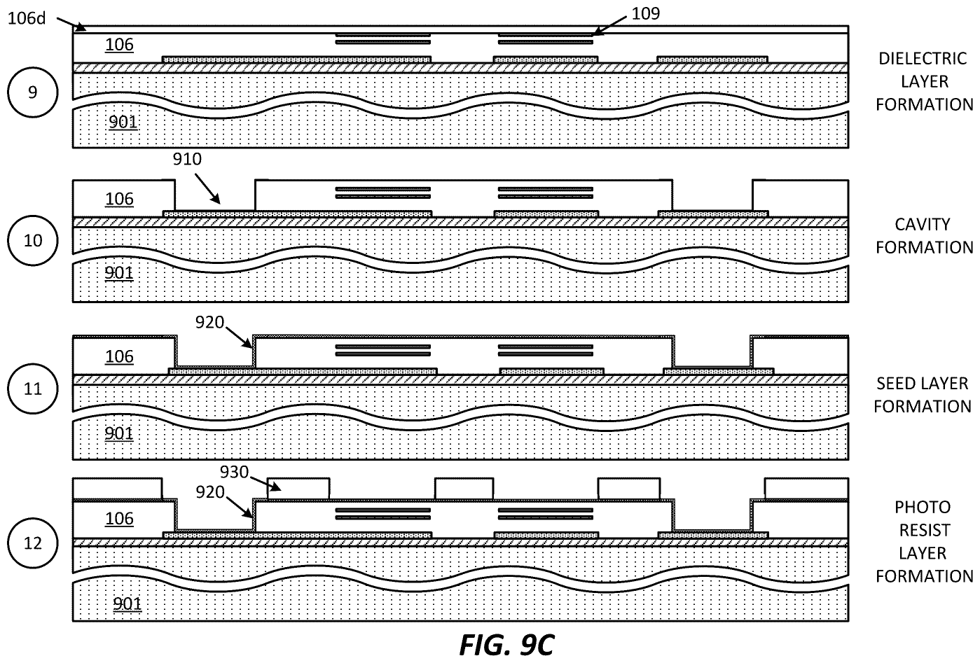

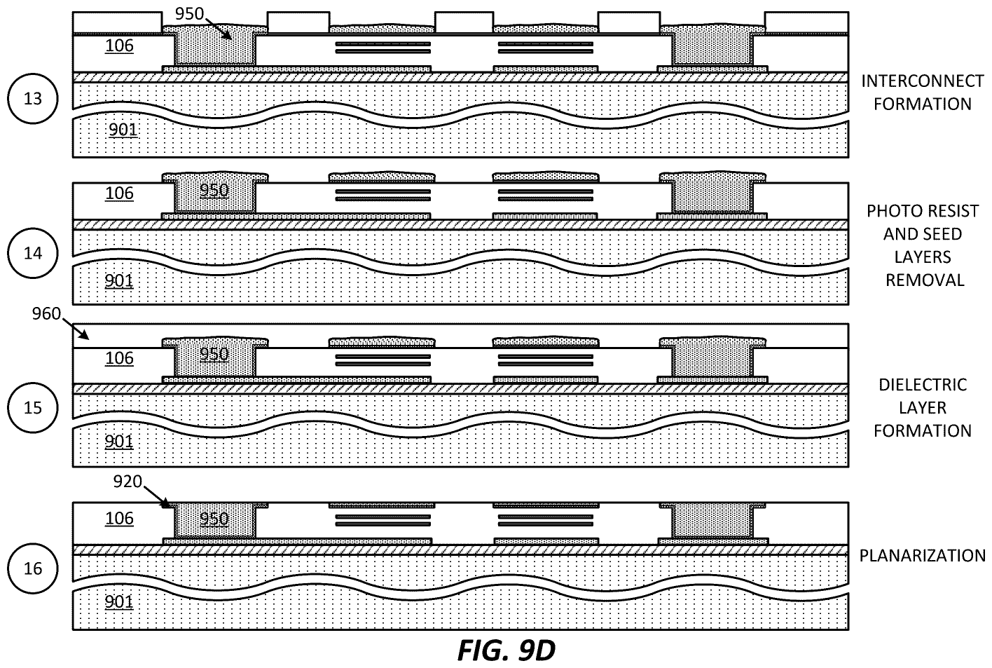

Stage 1, as shown in FIG. 5A, illustrates a state after a carrier 901, a piezoelectric layer 108, at least one dielectric layer 106, at least one material layer 109, a plurality of interconnects 130, a seed layer 920 and a plurality of interconnects 950. The carrier 901 may include silicon (Si) or sapphire. The piezoelectric layer 108 is coupled to the carrier 901. The plurality of interconnects 130 are coupled to the piezoelectric layer 108. The at least one dielectric layer 106 is coupled to the piezoelectric layer 108 and the plurality of interconnects 130. The plurality of interconnects 950 may include the seed layer 920. The plurality of interconnects 950 may include via interconnects and/or pad interconnects. The at least one material layer 109 is located in the at least one dielectric layer 106. An example of providing and/or fabricating the carrier 901, the piezoelectric layer 108, the at least one dielectric layer 106, the at least one material layer 109, the plurality of interconnects 130 and the plurality of interconnects 950 is shown and described below in at least FIGS. 9A-9D. In some implementations, stage 1 illustrates a wafer (e.g., first wafer) that includes a carrier 901, a piezoelectric layer 108, at least one dielectric layer 106, at least one material layer 109, a plurality of interconnects 130, a seed layer 920 and a plurality of interconnects 950.

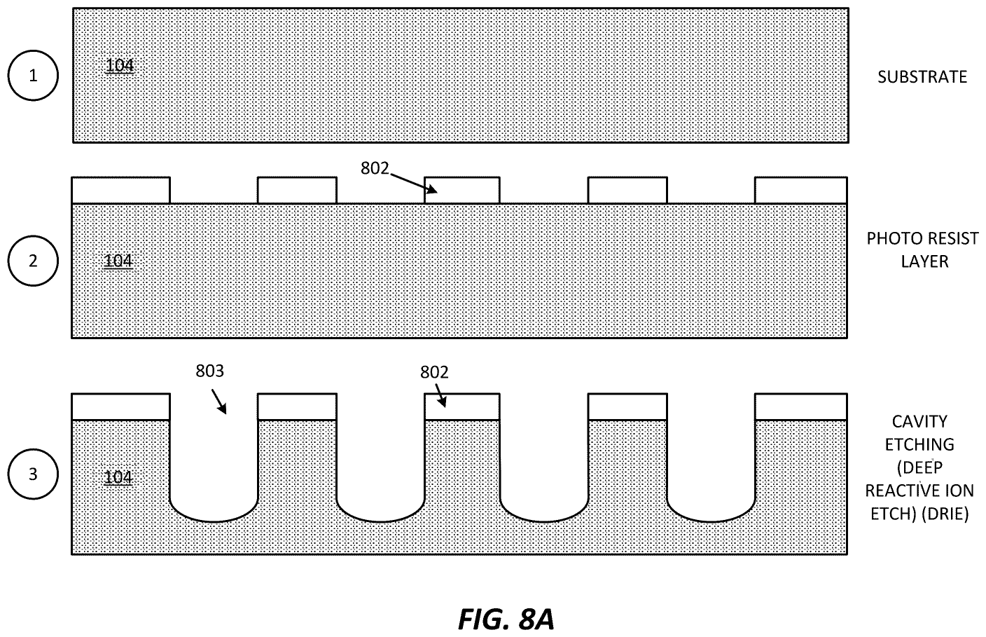

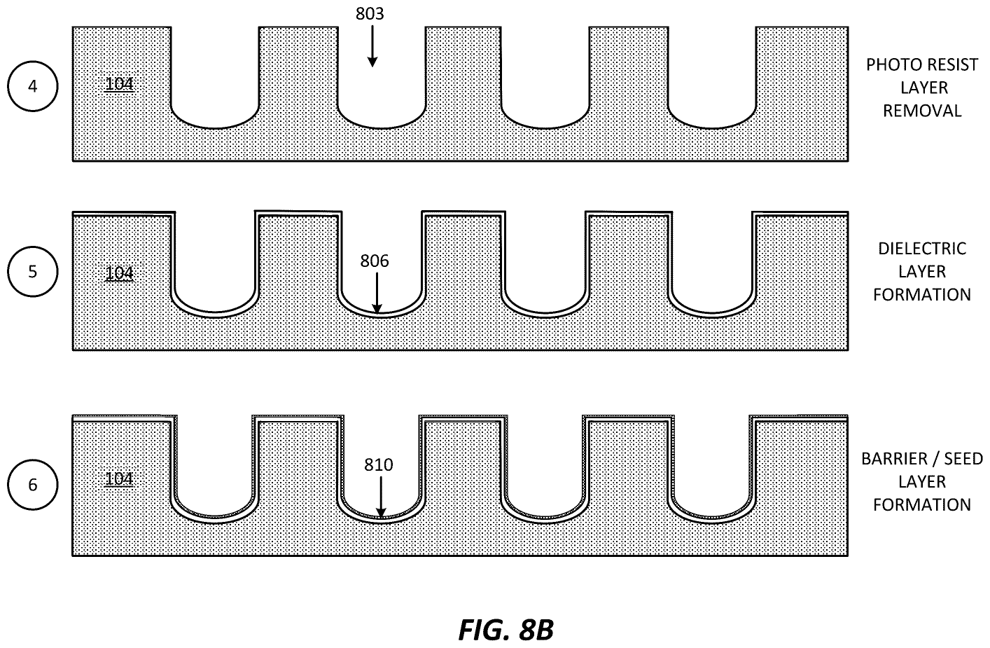

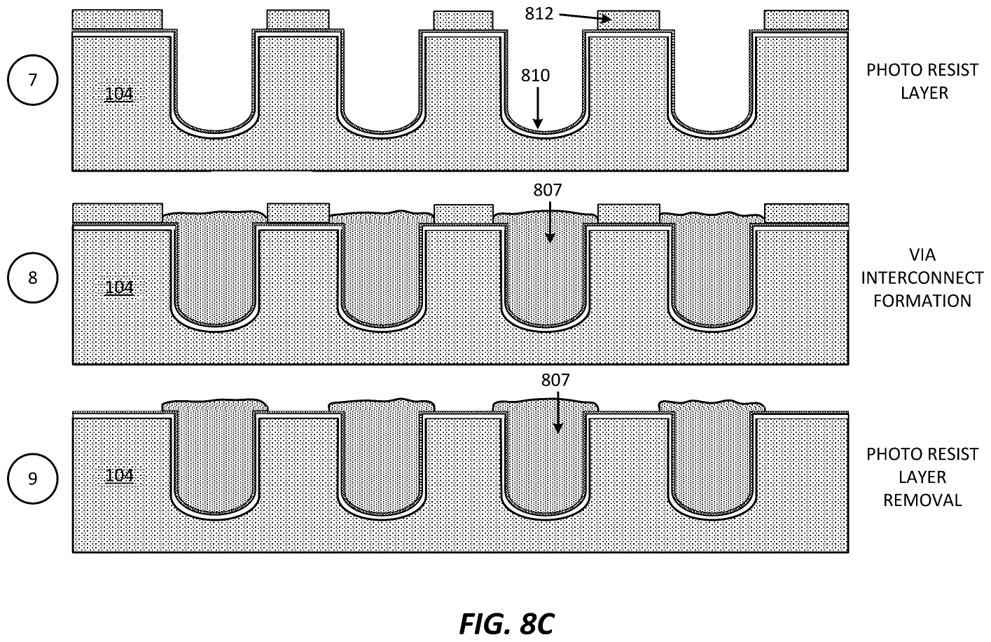

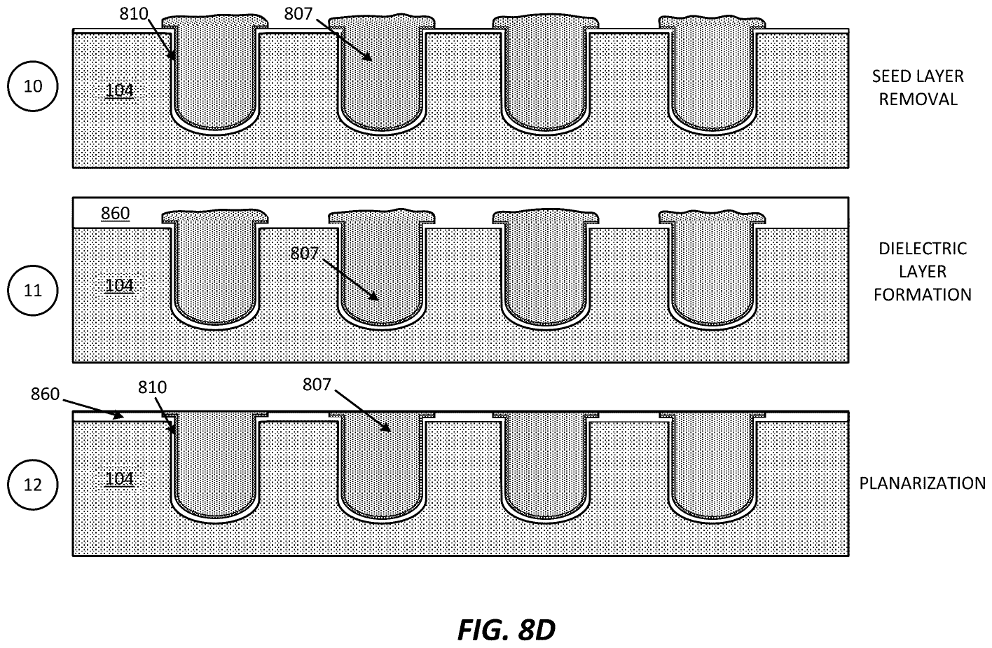

Stage 2 illustrates a state after a substrate 104, a plurality of interconnects 807, at least one seed layer 810 and a dielectric layer 806 are provided. The seed layer 810 may include one or more metal layers (e.g., a barrier layer and a seed layer). The plurality of interconnects 807 may include a plurality of via interconnects and a plurality of pad interconnects. An example of providing and/or fabricating a substrate with interconnects is shown and described below in at least FIGS. 8A-8D. In some implementations, stage 2 illustrates a wafer (e.g., second wafer) that includes a substrate 104, a plurality of interconnects 807, at least one seed layer 810 and a dielectric layer 806.

Stage 3 illustrates a state after a wafer (e.g., first wafer) that includes a carrier 901, a piezoelectric layer 108, at least one dielectric layer 106, at least one material layer 109, a plurality of interconnects 130, a seed layer 920 and a plurality of interconnects 950, is coupled to another wafer (e.g., second wafer) that includes a substrate 104, a plurality of interconnects 807, at least seed layer 810 (e.g., at least one barrier and seed layer) and a dielectric layer 806. A hybrid bonding process may be used to couple the first wafer to the second wafer. After the coupling process and/or the bonding process, stage 3 may illustrate the carrier 901, the piezoelectric layer 108, the dielectric layer 106, the at least one material layer 109, the plurality of via interconnects 105, the seed layer 305 and the substrate 104. The at least one dielectric layer 106 may represent the at least one dielectric layer 106 and the at least one dielectric layer 806. The plurality of via interconnects 105 may represent the combination of the plurality of interconnects 950 and the plurality of interconnects 807. Stage 3 illustrates a bond interface 260 that conceptually shows where the first wafer is coupled to the second wafer. The bond interface 260 may not be visible after the coupling of the first wafer to the second wafer.

Stage 4, as shown in FIG. 5B, illustrates a state after the carrier 901 is removed. The carrier 901 may be detached from the piezoelectric layer 108.

Stage 5 illustrates a state after the piezoelectric layer 108 is patterned, a plurality of interconnects 131 are formed and a metal layer 330 is formed. An etching process, an exposure process, a development process, sputtering process, evaporation process may be used to pattern the piezoelectric layer, form the plurality of interconnects 131 and/or form the metal layer 330.

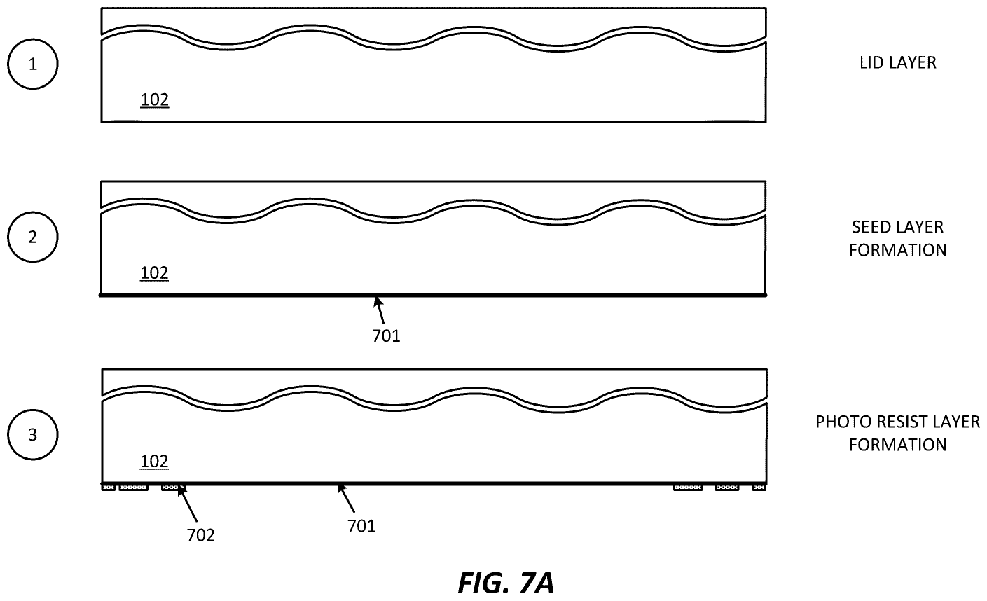

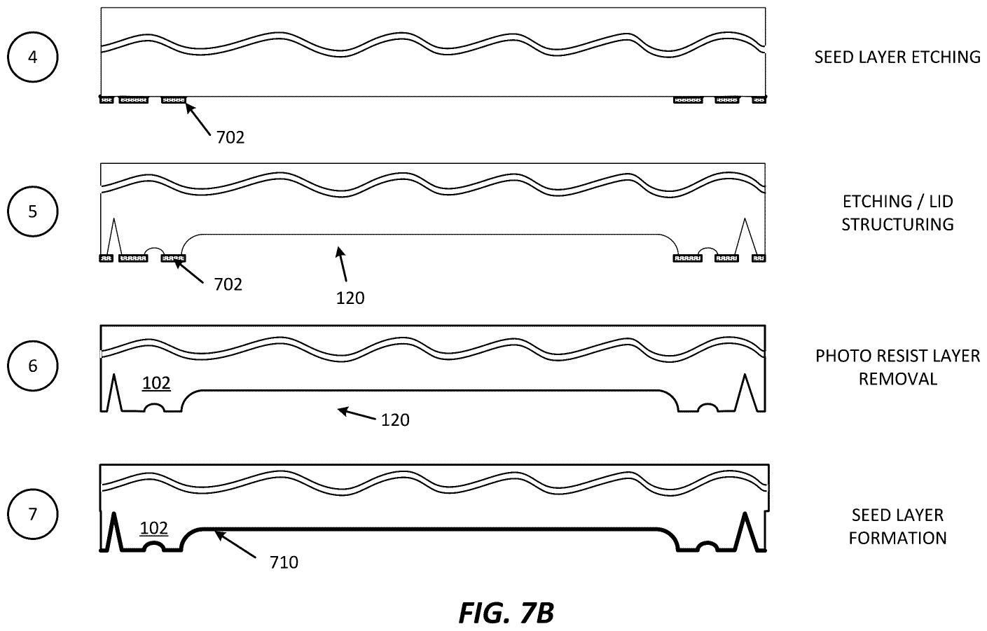

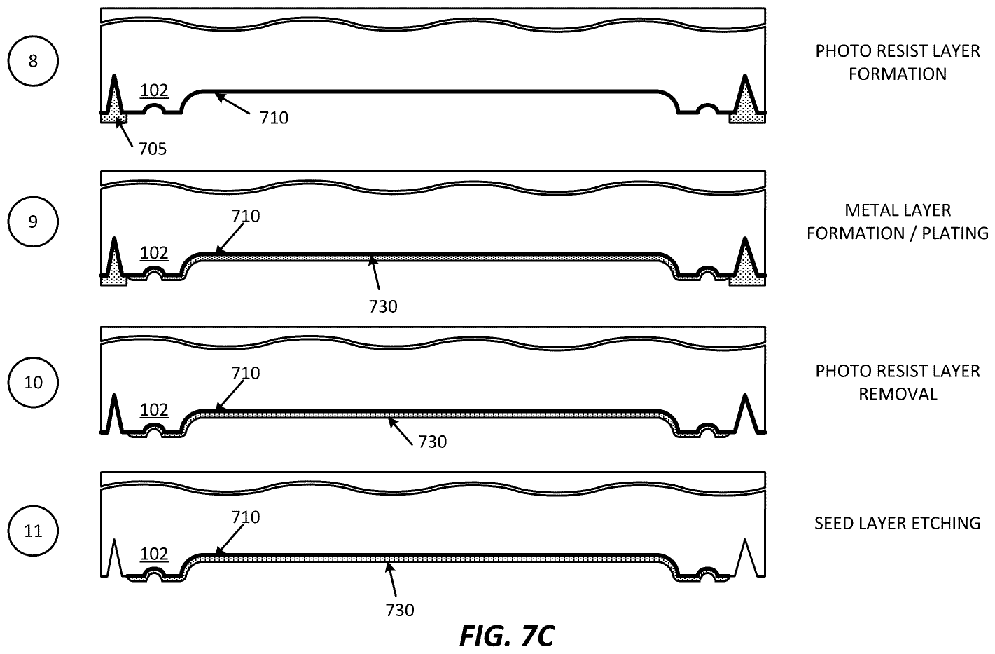

Stage 6, as shown in FIG. 5C, illustrates a state after a lid layer 102 and a metal layer 121 are provided and coupled to the metal layer 330. The lid layer 102 and the metal layer 121 may be fabricated. An example of providing and/or fabricating a lid layer is shown and described below in at least FIGS. 7A-7C. In some implementations, the lid layer 102 may include glass, silicon, fused silica, ceramic, or a combination thereof. The metal layer 121 may include titanium and/or copper. The metal layer 121 may be formed and/or disposed on one or more surfaces of the lid layer 102. However, different implementations may use different materials for the metal layer 121 and/or the lid layer 102. A cavity 120 may be located between the lid layer 102 and the piezoelectric layer 108. The metal layer 121 and the metal layer 330 may help provide a hermetic seal between the lid layer 102 and the dielectric layer 106.

Stage 7, as shown in FIG. 5D, illustrates a state after a portion of the substrate 104 is removed. A grinding and etching process may be used to remove a portion of the substrate 104. A portion of the plurality of via interconnects 105 and/or the barrier and seed layer 305 may be exposed once a portion of the substrate 104 is removed.

Stage 8, as shown in FIG. 5E, illustrates a state after a portion of the seed layer 305 is removed. The seed layer 305 may be a barrier layer. An etching process may be used to remove portions of the seed layer 305.

Stage 9, as shown in FIG. 5F, illustrates a state after a dielectric layer 506 is formed and coupled to the substrate 104 and the plurality of via interconnects 105. The dielectric layer 506 is sputtered or chemical deposited on a surface of the substrate 104 and a surface of the plurality of via interconnects 105. The dielectric layer 506 may be the same and/or similar to the dielectric layer 106. The dielectric layer 506 may include silicon dioxide (SiO₂).

Stage 10, as shown in FIG. 5G, illustrates a state after portions of the dielectric layer 506 and portions of the plurality of via interconnects 105 are removed. A planarization process may be used to remove portions of the dielectric layer 506 and portions of the plurality of via interconnects 105. A polishing (planarization)process may be used to remove portions of the dielectric layer 506 and portions of the plurality of via interconnects 105. Different implementations may have a plurality of interconnects 105 with side walls that are partially or completely covered with the seed layer 305.

Stage 11 illustrates a state after a plurality of metallization interconnects 150 are formed and coupled to the plurality of via interconnects 105. A metal layer 350 and a metal layer 550 may also be formed. The metal layer 350 may be formed and coupled to a surface of the plurality of metallization interconnects 150. The metal layer 550 may be formed and coupled to a surface of the metal layer 350. The metal layer 550 may include a different material from the metal layer 350. The metal layer 350 may include a different material from the plurality of metallization interconnects 150. One or more plating processes may be used to form the plurality of metallization interconnects 150, the metal layer 350 and/or the metal layer 550. Different implementations may have different number of metal layers. Different implementations may have the metal layer 350 and/or the metal layer 550 located on different surfaces of the plurality of metallization interconnects 150. For example, in some implementations, the metal layer 350 and/or the metal layer 550 may be coupled to side surfaces of the plurality of metallization interconnects 150.

Stage 12, as shown in FIG. 5H, illustrates a state after a plurality of solder interconnects 112 are coupled to the plurality of metallization interconnects 150, the metal layer 350 and/or the metal layer 550. A solder reflow process may be used to form and couple the plurality of solder interconnects 112 to the plurality of metallization interconnects 150, the metal layer 350 and/or the metal layer 550.

Stage 13 illustrates a state after the lid layer 102 is thinned. For example, a portion of the lid layer 102 may be removed through a grinding process. With the thinning the lid layer may be separated into individual lid portions.

Different implementations may use different processes for forming the metal layer(s) and/or interconnects. In some implementations, a chemical vapor deposition (CVD) process, a physical vapor deposition (PVD) process (sputtering, evaporation)a spray coating process, and/or a plating process may be used to form the metal layer(s).

### Exemplary Flow Diagram of a Method for Fabricating a Device Comprising an Acoustic Layer and at Least One Via Interconnect

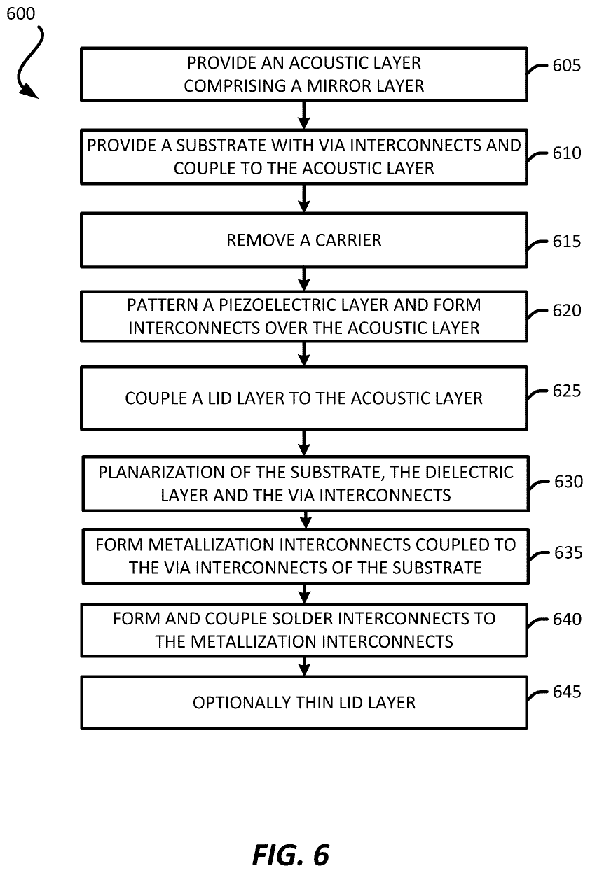

In some implementations, fabricating a device includes several processes. FIG. 6 illustrates an exemplary flow diagram of a method 600 for providing or fabricating a device that includes an acoustic layer and at least one via interconnect. In some implementations, the method 600 of FIG. 6 may be used to provide or fabricate the device 300 described in the disclosure. However, the method 600 may be used to provide or fabricate any of the devices described in the disclosure.

It should be noted that the method 600 of FIG. 6 may combine one or more processes in order to simplify and/or clarify the method for providing or fabricating a device. In some implementations, the order of the processes may be changed or modified.

The method provides (at 605) an acoustic layer comprising a mirror layer. Stage 1 of FIG. 5A, illustrates and describes an example of a state after a carrier 901, a piezoelectric layer 108, at least one dielectric layer 106, at least one material layer 109, a plurality of interconnects 130, a seed layer 920 and a plurality of interconnects 950. The piezoelectric layer 108, the at least one dielectric layer 106, the at least one material layer 109, the plurality of interconnects 130, the seed layer 920 and the plurality of interconnects 950 may be considered part of an acoustic layer with a mirror layer. The carrier 901 may include silicon (Si) or sapphire. The piezoelectric layer 108 is coupled to the carrier 901. The plurality of interconnects 130 are coupled to the piezoelectric layer 108. The at least one dielectric layer 106 is coupled to the piezoelectric layer 108 and the plurality of interconnects 130. The plurality of interconnects 950 may include the seed layer 920. The plurality of interconnects 950 may include via interconnects and/or pad interconnects. The at least one material layer 109 is located in the at least one dielectric layer 106. An example of providing and/or fabricating the carrier 901, the piezoelectric layer 108, the at least one dielectric layer 106, the at least one material layer 109, the plurality of interconnects 130 and the plurality of interconnects 950 is shown and described below in at least FIGS. 9A-9D. In some implementations, stage 1 illustrates a wafer (e.g., first wafer) that includes a carrier 901, a piezoelectric layer 108, at least one dielectric layer 106, at least one material layer 109, a plurality of interconnects 130, a seed layer 920 and a plurality of interconnects 950.

The method provides (at 610) a substrate, at least one dielectric layer and a plurality of interconnects and couples (at 610) the substrate, the at least one dielectric layer and the plurality of interconnects to the acoustic layer. Stage 2 of FIG. 5A, illustrates and describes an example of a state after a substrate 104, a plurality of interconnects 807, at least one seed layer 810 (e.g., at least one barrier and seed layer) and a dielectric layer 806 are provided. The plurality of interconnects 807 may include a plurality of via interconnects and a plurality of pad interconnects. An example of providing and/or fabricating a substrate with interconnects is shown and described below in at least FIGS. 8A-8D. In some implementations, stage 2 illustrates a wafer (e.g., second wafer) that includes a substrate 104, a plurality of interconnects 807, at least one seed layer 810 (e.g., at least one barrier and seed layer) and a dielectric layer 806.

As mentioned above, the method couples (at 610) the substrate to an acoustic layer. Stage 3 of FIG. 5A, illustrates and describes an example of a state after a wafer (e.g., first wafer) that includes a carrier 901, a piezoelectric layer 108, at least one dielectric layer 106, at least one material layer 109, a plurality of interconnects 130, a seed layer 920 and a plurality of interconnects 950, is coupled to another wafer (e.g., second wafer) that includes a substrate 104, a plurality of interconnects 807, at least one seed layer 810 (e.g., at least one barrier and seed layer) and a dielectric layer 806. A hybrid bonding process may be used to couple the first wafer to the second wafer. After the coupling process and/or the bonding process, stage 3 may illustrate the carrier 901, the piezoelectric layer 108, the dielectric layer 106, the at least one material layer 109, the plurality of via interconnects 105, the seed layer 305 and the substrate 104. The at least one dielectric layer 106 may represent the at least one dielectric layer 106 and the at least one dielectric layer 806. The plurality of via interconnects 105 may represent the combination of the plurality of interconnects 950 and the plurality of interconnects 807. Stage 3 illustrates a bond interface 260 that conceptually shows where the first wafer is coupled to the second wafer. The bond interface 260 may not be visible after the coupling of the first wafer to the second wafer.

The method removes (at 615) the carrier. Stage 4 of FIG. 5B, illustrates and describes an example of a state after the carrier 901 is removed. The carrier 901 may be detached from the piezoelectric layer 108.

The method patterns (at 620) a piezoelectric layer and forms a plurality of interconnects. Stage 5 of FIG. 5B, illustrates and describes an example of a state after the piezoelectric layer 108 is patterned, a plurality of interconnects 131 are formed and a metal layer 330 is formed. An etching process, an exposure process, a development process, sputtering process, evaporation process may be used to pattern the piezoelectric layer, form the plurality of interconnects 131 and/or form the metal layer 330.

The method couples (at 625) a lid layer to the acoustic layer. Stage 6 of FIG. 5C, illustrates and describes an example of a state after a lid layer 102 and a metal layer 121 are provided and coupled to the metal layer 330. The lid layer 102 and the metal layer 121 may be fabricated. An example of providing and/or fabricating a lid layer is shown and described below in at least FIGS. 7A-7C. In some implementations, the lid layer 102 may include glass, silicon, fused silica, ceramic, or a combination thereof. The metal layer 121 may include titanium and/or copper. The metal layer 121 may be formed and/or disposed on one or more surfaces of the lid layer 102. However, different implementations may use different materials for the metal layer 121 and/or the lid layer 102. A cavity 120 may be located between the lid layer 102 and the piezoelectric layer 108. The metal layer 121 and the metal layer 330 may help provide a hermetic seal between the lid layer 102 and the dielectric layer 106.

The method planarizes (at 630) the substrate, the dielectric layer and the plurality of via interconnects. Stage 7 of FIG. 5D through stage 10 of FIG. 5G, illustrate examples of planarizing the substrate, the dielectric layer and/or the plurality of via interconnects.

Stage 7 of FIG. 5D, illustrates and describes an example of a state after a portion of the substrate 104 is removed. An etching process may be used to remove a portion of the substrate 104. A portion of the plurality of via interconnects 105 and/or the seed layer 305 may be exposed once a portion of the substrate 104 is removed.

Stage 8 of FIG. 5E, illustrates and describes an example of a state after a portion of the seed layer 305 is removed. The seed layer 305 may be a barrier layer. An etching process may be used to remove portions of the seed layer 305.

Stage 9 of FIG. 5F, illustrates and describes an example of a state after a dielectric layer 506 is formed and coupled to the substrate 104 and the plurality of via interconnects 105. The dielectric layer 506 may chemical or physical deposited on a surface of the substrate 104 and a surface of the plurality of via interconnects 105. The dielectric layer 506 may be the same and/or similar to the dielectric layer 106. The dielectric layer 506 may include silicon dioxide (SiO₂).

Stage 10 of FIG. 5G, illustrates and describes an example of a state after portions of the dielectric layer 506 and portions of the plurality of via interconnects 105 are removed. A planarization process may be used to remove portions of the dielectric layer 506 and portions of the plurality of via interconnects 105. A polishing process may be used to remove portions of the dielectric layer 506 and portions of the plurality of via interconnects 105.

The method forms (at 635) a plurality of metallization interconnects that are coupled to the plurality of via interconnects. Stage 11 of FIG. 5G, illustrates and describes an example of a state after a plurality of metallization interconnects 150 are formed and coupled to the plurality of via interconnects 105. A metal layer 350 and a metal layer 550 may also be formed. The metal layer 350 may be formed and coupled to a surface of the plurality of metallization interconnects 150. The metal layer 550 may be formed and coupled to a surface of the metal layer 350. The metal layer 550 may include a different material from the metal layer 350. The metal layer 350 may include a different material from the plurality of metallization interconnects 150. One or more plating processes may be used to form the plurality of metallization interconnects 150, the metal layer 350 and/or the metal layer 550. Different implementations may have different number of metal layers.

The method forms and couples (at 640) a plurality of solder interconnects to the plurality of metallization interconnects. Stage 12 of FIG. 5H, illustrates and describes an example of a state after a plurality of solder interconnects 112 are coupled to the plurality of metallization interconnects 150, the metal layer 350 and/or the metal layer 550. A solder reflow process may be used to form and couple the plurality of solder interconnects 112 to the plurality of metallization interconnects 150, the metal layer 350 and/or the metal layer 550.

The method optionally (at 645) thins the lid layer. Stage 13 of FIG. 5H illustrates a state after the lid layer 102 is thinned. For example, a portion of the lid layer 102 may be removed through a grinding process.

Different implementations may use different processes for forming the metal layer(s) and/or interconnects. In some implementations, a chemical vapor deposition (CVD) process, a physical vapor deposition (PVD) process (sputtering, evaporation) a spray coating process, and/or a plating process may be used to form the metal layer(s).

### Exemplary Sequence for Fabricating a Lid Layer

In some implementations, fabricating a lid layer includes several processes. FIGS. 7A-7C illustrate an exemplary sequence for providing or fabricating a lid layer. In some implementations, the sequence of FIGS. 7A-7C may be used to provide or fabricate the lid layer 102. However, the process of FIGS. 7A-7C may be used to fabricate any of the lid layers described in the disclosure.

It should be noted that the sequence of FIGS. 7A-7C may combine one or more stages in order to simplify and/or clarify the sequence for providing or fabricating a lid layer. In some implementations, the order of the processes may be changed or modified. In some implementations, one or more of processes may be replaced or substituted without departing from the scope of the disclosure.

Stage 1, as shown in FIG. 7A, illustrates a state after a lid layer 102 is provided. The lid layer 102 may include glass, silicon (Si), fused silica, ceramic, or combinations thereof. Stage 2 illustrates a state after a seed layer 701 is formed on a surface of the lid layer 102. A sputtering process may be used to form the seed layer 701 on the lid layer 102. The seed layer 701 may include copper and/or chromium. Stage 3 illustrates a state after a photo resist layer 702 is formed on the seed layer 701. The photo resist layer 702 may be disposed on the seed layer 701.

Stage 4, as shown in FIG. 7B, illustrates a state after portions of the seed layer 701 are removed. The seed layer 701 may be etched out in portions that are not covered by the photo resist layer 702. Stage 5 illustrates a state after a plurality of cavities 120 are formed in the lid layer 102. An etching process may also be used to form the plurality of cavities 120. Stage 5 may illustrate a state after a lid structuring process. Stage 6 illustrates a state after the photo resist layer 702 and any remaining seed layer (e.g., 701) are removed and/or detached. Stage 7 illustrates a state after a seed layer 710 is formed on a surface of the lid layer 102. A sputtering process may be used to form the seed layer 710 on the lid layer 102. The seed layer 710 may include one or more metal layers. The seed layer 710 may include titanium and/or copper.

Stage 8, as shown in FIG. 7C, illustrates a state after a photo resist layer 705 is formed over portions of the lid layer 102. Stage 9 illustrates a state after a metal layer 730 is formed over exposed portions of the seed layer 710 (e.g., portions of the seed layer 710 that are not covered by the photo resist layer 705). A plating process may be used to form the metal layer 730. Stage 10 illustrates a state after the photo resist layer 705 is removed and/or detached. Stage 11 illustrates a state after portions of the seed layer 710 are removed. For example, portions of the seed layer 710 that are not covered by the metal layer 730 may be removed. An etching process may be used to remove portions of the seed layer 710. The seed layer 710 and the metal layer 730 may represent the metal layer 121, as described in at least FIGS. 1-4.

### Exemplary Sequence for Fabricating a Substrate With Via Interconnects

In some implementations, fabricating a substrate with via interconnects includes several processes. FIGS. 8A-8D illustrate an exemplary sequence for providing or fabricating a substrate with via interconnects. In some implementations, the sequence of FIGS. 8A-8D may be used to provide or fabricate the substrate 104 with via interconnects. However, the process of FIGS. 8A-8D may be used to fabricate any of the substrates described in the disclosure.

It should be noted that the sequence of FIGS. 8A-8D may combine one or more stages in order to simplify and/or clarify the sequence for providing or fabricating a substrate with via interconnects. In some implementations, the order of the processes may be changed or modified. In some implementations, one or more of processes may be replaced or substituted without departing from the scope of the disclosure.

Stage 1, as shown in FIG. 8A, illustrates a state after a substrate 104 is provided. The substrate 104 may include silicon (Si). Stage 2 illustrates a state after a photo resist layer 802 is provided over a surface of the substrate 104. Stage 3 illustrates a state after a plurality of cavities 803 are formed in the substrate 104. An etching process may be used to form the plurality of cavities 803 in the substrate 104. The etching process may include deep reactive ion etch (DRIE).

Stage 4, as shown in FIG. 8B, illustrates a state after the photo resist layer 802 is removed and/or detached from the substrate 104. Stage 5 illustrates a state after a dielectric (e.g., isolation) layer 806 is formed over a surface of the substrate 104. The dielectric (e.g., isolation) layer 806 may be disposed in the plurality of cavities 803. A deposition process may be used to form the dielectric (e.g., isolation) layer 806. The dielectric (e.g., isolation) layer 806 may include silicon dioxide. The dielectric layer 806 may be formed by thermal oxidation. However, different implementations may use different materials for the dielectric (e.g., isolation) layer 806. Stage 6 illustrates a state after a seed layer 810 is formed over the dielectric (e.g., isolation) layer 806. The seed layer 810 may include one or more metal layers. The seed layer 810 may include a barrier layer and seed layer. A sputtering process or chemical deposition (e.g., chemical vapor deposition, atomic layer deposition) may be used to form the barrier and seed layers 810. The seed layer 810 may include a metal layer, such as titanium and/or copper. The barrier layer ay include metal nitrides or metal carbides. The barrier and seed layers 810 may be formed over the dielectric layer 806.

Stage 7, as shown in FIG. 8C, illustrates a state after a photo resist layer 812 is disposed over the seed layer 810. Stage 8 illustrates a state after a plurality of interconnects 807 are formed over the seed layer 810. A plating process may be used to form the plurality of interconnects 807. The plurality of interconnects 807 may be coupled to the seed layer 810. The plurality of interconnects 807 may be formed in the plurality of cavities 803. The plurality of interconnects 807 may include via interconnects and pad interconnects. Stage 9 illustrates a state after the photo resist layer 812 is removed and/or detached.

Stage 10, as shown in FIG. 8D illustrates a state after portions of the seed layer 810 are removed. The portions of the seed layer 810 that were previously covered by the photo resist layer 812 may be etched out. Stage 11 illustrates a state after a dielectric layer 860 is formed over the substrate 104, the plurality of interconnects 807 and the dielectric layer 806. A deposition process may be used to form the dielectric layer 860. The dielectric layer 860 may be the same material or a similar material as the dielectric layer 806. Stage 12 illustrates a state after planarization of the plurality of interconnects 807 and the dielectric layer 860. Portions of the plurality of interconnects 807 and portions of the dielectric layer 860 may be removed.

### Exemplary Sequence for Fabricating an Acoustic Layer

In some implementations, fabricating an acoustic layer includes several processes. FIGS. 9A-9D illustrate an exemplary sequence for providing or fabricating an acoustic layer. In some implementations, the sequence of FIGS. 9A-9D may be used to provide or fabricate the acoustic layer 101. However, the process of FIGS. 9A-9D may be used to fabricate any of the acoustic layers described in the disclosure.

It should be noted that the sequence of FIGS. 9A-9D may combine one or more stages in order to simplify and/or clarify the sequence for providing or fabricating an acoustic layer. In some implementations, the order of the processes may be changed or modified. In some implementations, one or more of processes may be replaced or substituted without departing from the scope of the disclosure.

Stage 1, as shown in FIG. 9A, illustrates a state after a carrier 901, a piezoelectric layer 108 and a metal layer 902 are provided. The carrier 901 may include sapphire or silicon (Si). The piezoelectric layer 108 may be coupled to a surface of the carrier 901. The metal layer 902 may be coupled to the piezoelectric layer 108. Stage 2 illustrates a state after the metal layer 902 is etched to form a patterned metal layer. An etching process may be used to pattern the metal layer 902. The patterning of the metal layer 902 may form and/or define a plurality of interconnects 130. Stage 3 illustrates a state after a dielectric layer 106a is formed over the piezoelectric layer 108 and the metal layer 902. A deposition process may be used to form the dielectric layer 106a. Stage 4 illustrates a state after a material layer 109a is formed over the dielectric layer 106a. The material layer 109a may have a different acoustic impedance from the acoustic impedance of the dielectric layer 106a. The material layer 109a may include an acoustic mirror layer. A sputtering or evaporation process may be used to form the material layer 109a.

Stage 5 illustrates a state after an additional dielectric layer 106b is formed over the existing dielectric layer 106a and the material layer 109a. A deposition process may be used to form the additional dielectric layer 106b. The dielectric layer 106b may be the same or similar material as the dielectric layer 106a. Stage 6 illustrates a state after a material layer 109b is formed over the dielectric layer 106b. The material layer 109b may have a different acoustic impedance from the acoustic impedance of the dielectric layer 106b. The material layer 109b may include an acoustic mirror layer. A sputtering or evaporation process may be used to form the material layer 109b. The material layer 109b may be the same or similar material as the material layer 109a. Stage 7 illustrates a state after an additional dielectric layer 106c is formed over the existing dielectric layer 106b and the material layer 109b. A deposition process may be used to form the additional dielectric layer 106c. The dielectric layer 106c may be the same or similar material as the dielectric layer 106b. Stage 8 illustrates a state after planarization. A portion of the dielectric layer 106 may be removed or polished off and may expose one of the material layer 109 (e.g., 109b). The dielectric layer 106 may represent the dielectric layer 106a, the dielectric layer 106b and the dielectric layer 106c.

Stage 9, as shown in FIG. 9C, illustrates a state after additional dielectric layer 106d is formed over the existing dielectric layer (e.g., 106, 106c) and the material layer 109. A deposition process may be used to form the additional dielectric layer 106d. Stage 10 illustrates a state after a plurality of cavities 910 are formed in the at least one dielectric layer 106. An exposure process, a development process and an etching process may be used to form the plurality of cavities 910 in the at least one dielectric layer 106. The dielectric layer 106 of stage 10 may represent the dielectric layer 106a, the dielectric layer 106b, the dielectric layer 106c and the dielectric layer 106d. Stage 11 illustrates a state after a seed layer 920 is formed. A sputtering process may be used to form the seed layer 920. The seed layer 920 may be formed over a surface of the at least one dielectric layer 106 including in the plurality of cavities 910. Stage 12 illustrates after a photo resist layer 930 is formed. The photo resist layer 930 may be formed over the seed layer 920.

Stage 13, as shown in FIG. 9D, a plurality of interconnects 950 are formed and coupled to the seed layer 920. The plurality of interconnects 950 may include via interconnects and pad interconnects. A plating process may be used to form the plurality of interconnects 950. The interconnects 950 may include copper. In some implementations, a physical deposition may be used (sputtering, evaporation). Stage 14 illustrates a state after the photo resist layer 930 is removed and/or detached. Stage 15 illustrates a state after a dielectric layer 960 is disposed over the plurality of interconnects 950 and the at least one dielectric layer 106. The dielectric layer 960 may include the same material or a similar material as the at least one dielectric layer 106. A deposition process may be used to form the dielectric layer 960. After the dielectric layer 960 is provided, the dielectric layer 960 may considered part of the at least one dielectric layer 106.

Stage 16 illustrates a state after planarization of the plurality of interconnects 950 and the dielectric layer 106. Portions of the plurality of interconnects 950 and portions of the dielectric layer 106 may be removed.

### Exemplary Device Comprising an Acoustic Layer and at Least One Via Interconnect

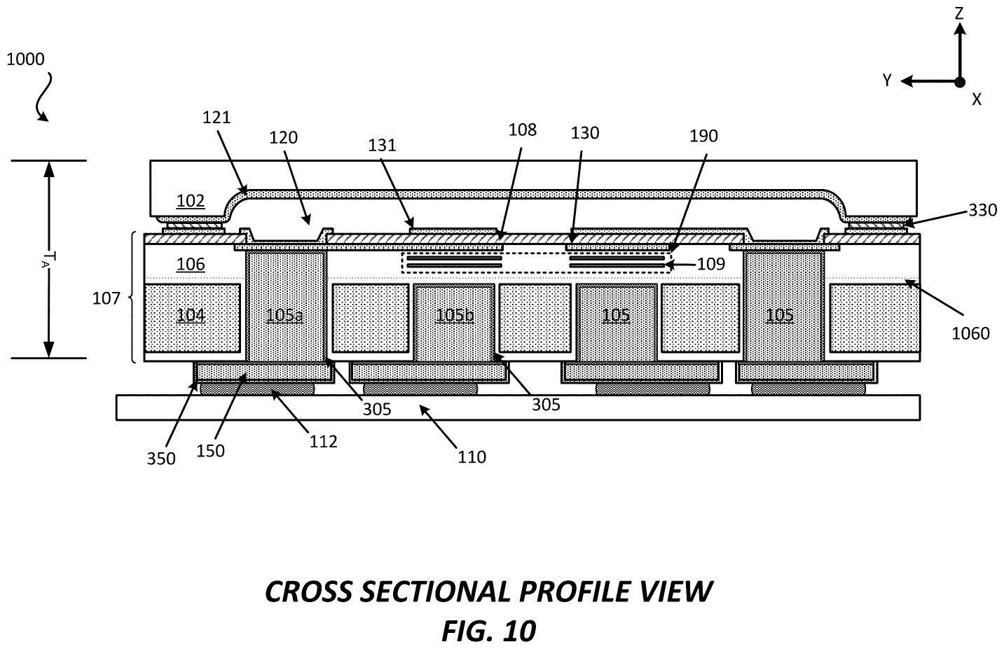

FIG. 10 illustrates a cross sectional profile view of a device 1000 that includes an acoustic layer and at least one via interconnect. The device 1000 may be similar to the device 100 of FIG. 1, the device 200 of FIG. 2, the device 300 of FIG. 3 and/or the device 400 of FIG. 4, and may include similar and/or the same components as described for the device 100, the device 200, the device 300 and/or the device 400. Thus, the description of the device 100, the device 200, the device 300 and/or the device 400 may be applicable to the device 100. The device 1000 includes a plurality of via interconnects 105 with a different design and/or configurations. The device 1000 may include a piezoelectric layer 108, a plurality of interconnects 130 and/or a plurality of interconnects 131 with a different design from the device 100, the device 200, the device 300 and/or the device 400. The lid layer 102 is coupled to the device base 107 through the metal layer 121 and the plurality of interconnects 130 and/or the plurality of interconnects 131. The plurality of via interconnects 105 include via interconnects with a more uniform width across the height of the via interconnect. For example, the via interconnect 105a may have a width or diameter that is approximately uniform (e.g., approximately the same) through the entire height of the via interconnect 105a. Similarly, the via interconnect 105b may have a width or diameter that is approximately uniform (e.g., approximately the same) through the entire height of the via interconnect 105b. The seed layer 305 may include a barrier layer and a seed layer. The barrier layer and seed layer 305 may be coupled to the plurality of via interconnects 105. The seed layer 305 (e.g., barrier layer and seed layer) may be considered part of the plurality of via interconnects 105.

FIG. 10 illustrates a bond interface 1060. The bond interface 1060 may be a conceptual representation of where different portions of the device base 107 may be coupled together to form the device base 107. The bond interface 1060 may not be visible nor detectable in the device base 107. For example, the dielectric layer 106 above the bond interface 1060 may not be separate from the dielectric layer 106 below the bond interface 1060. The dielectric layer 106 above the bond interface 1060 may be continuous and/or contiguous to the dielectric layer 106 below the bond interface 1060.

### Exemplary Sequence for Fabricating a Device Comprising an Acoustic Layer and at Least One Via Interconnect

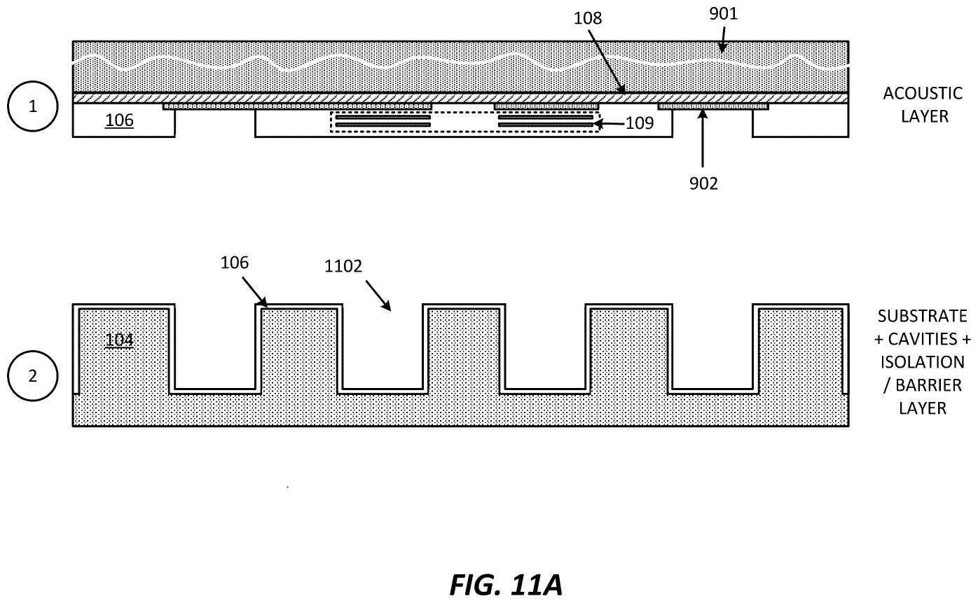

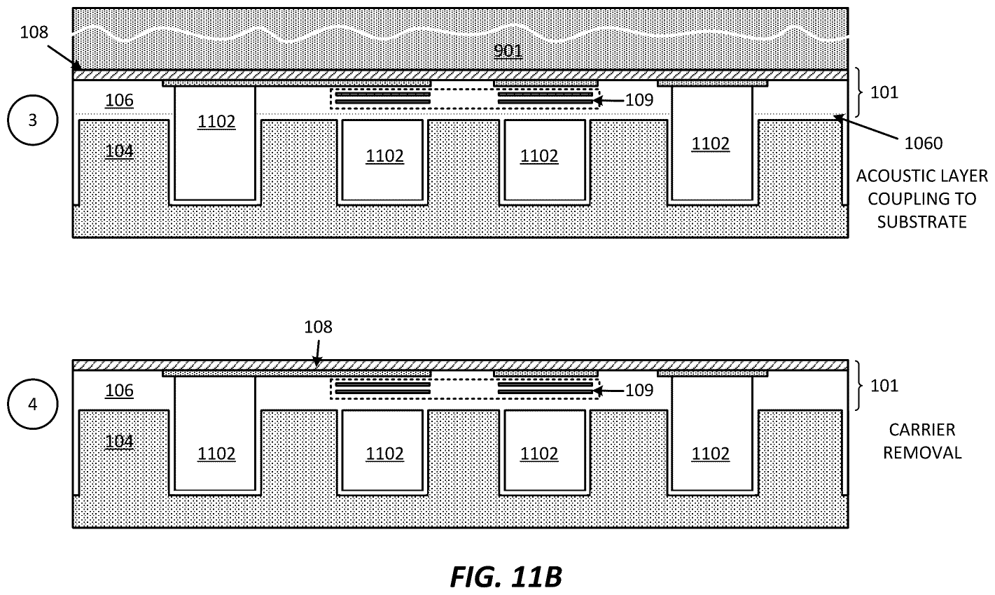

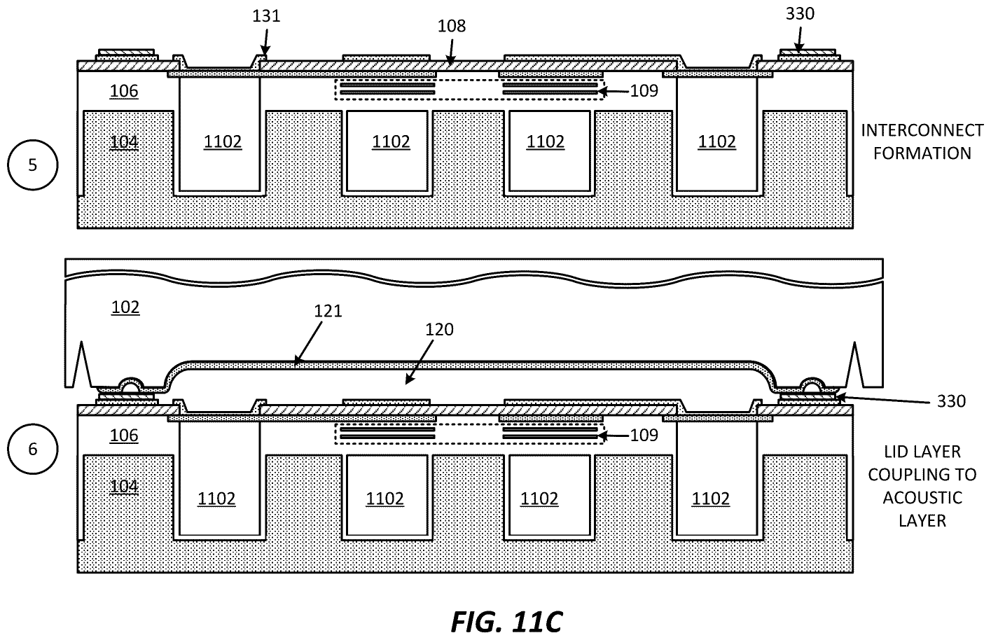

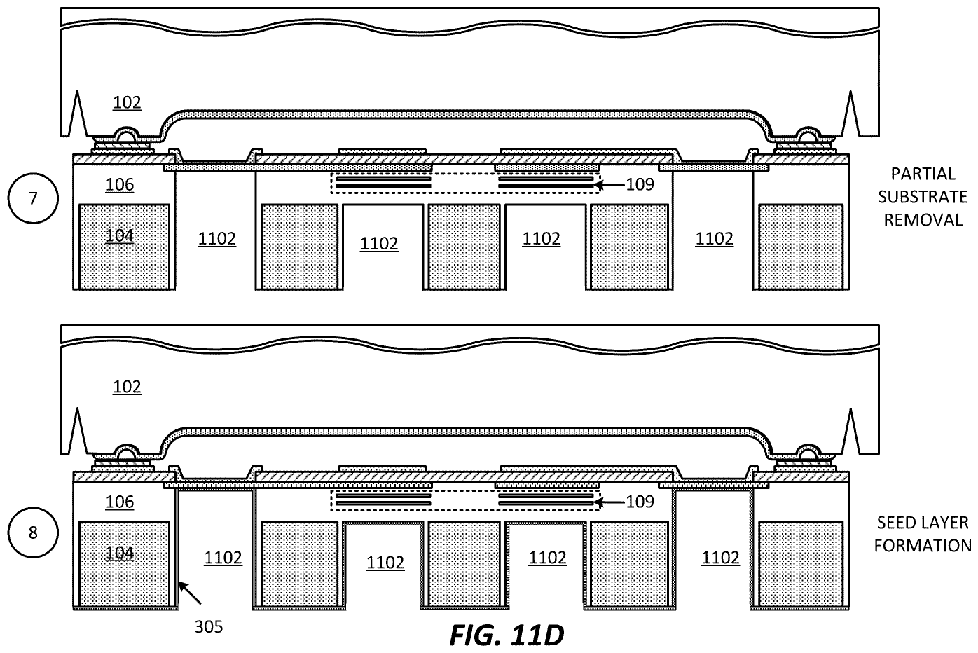

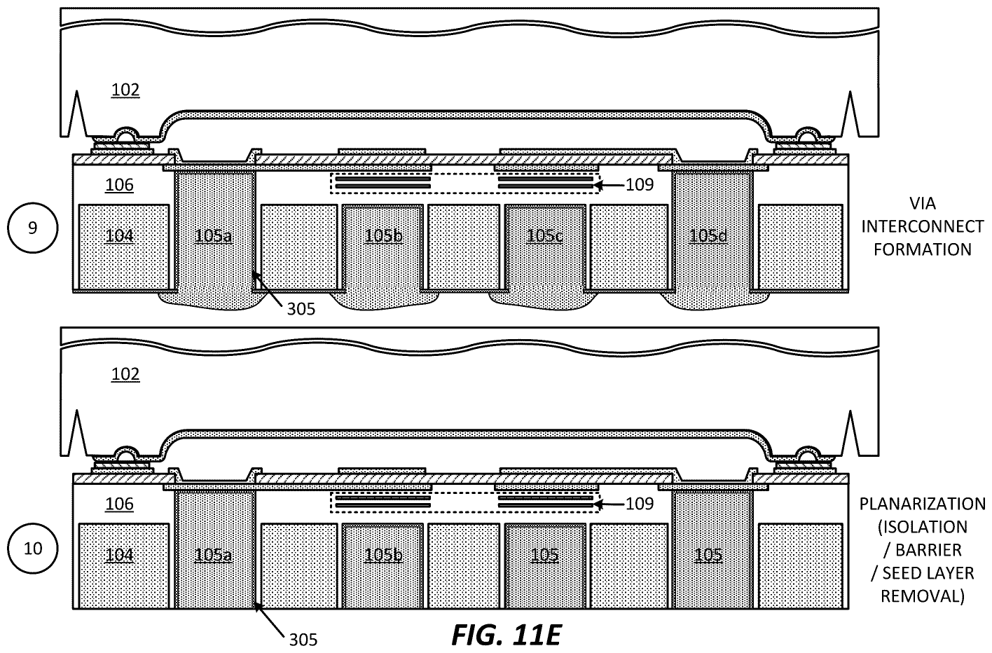

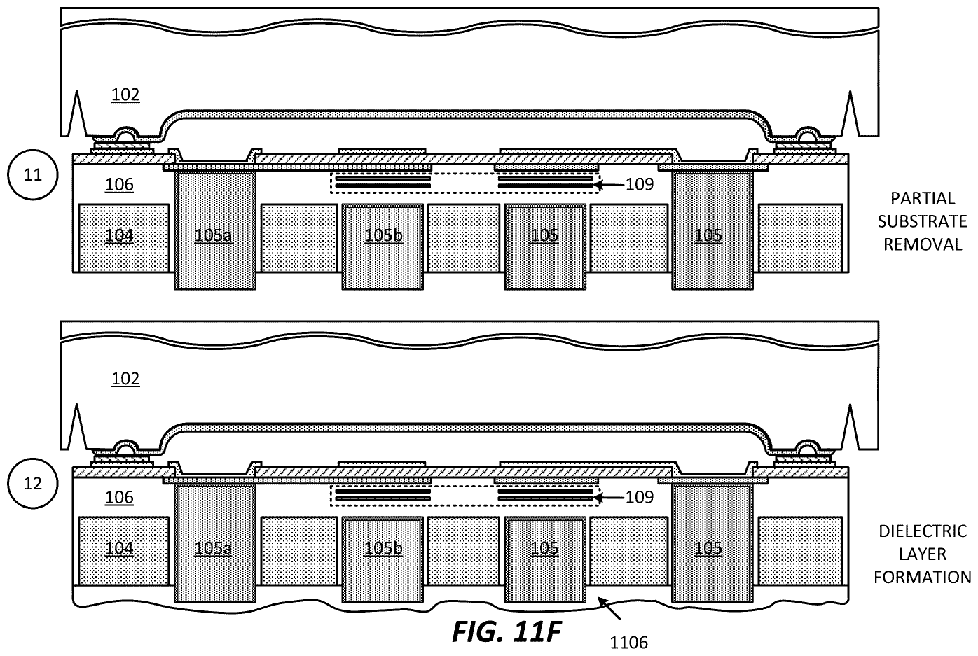

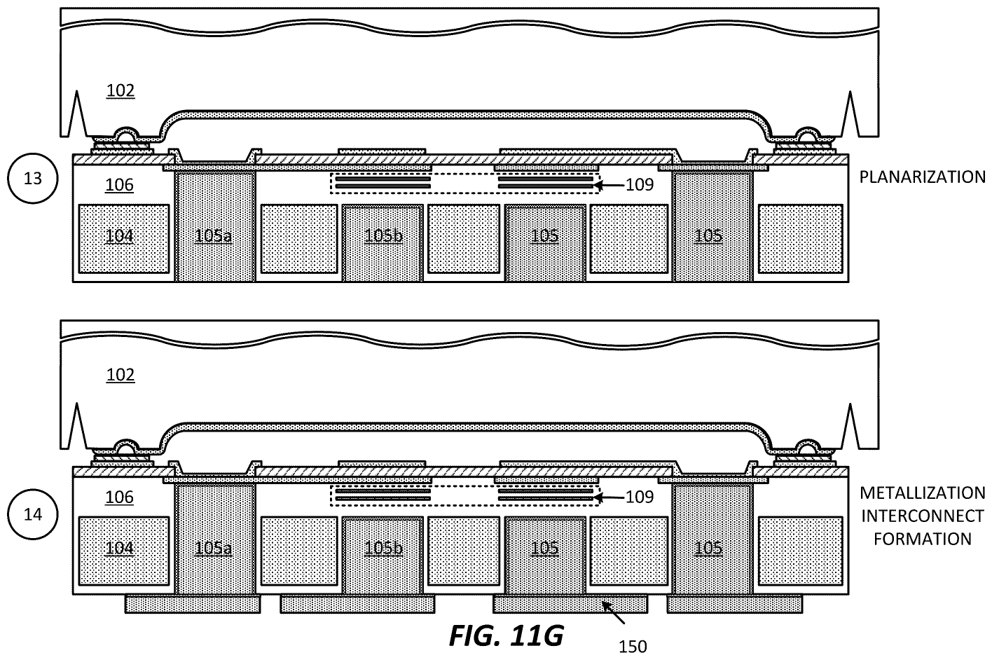

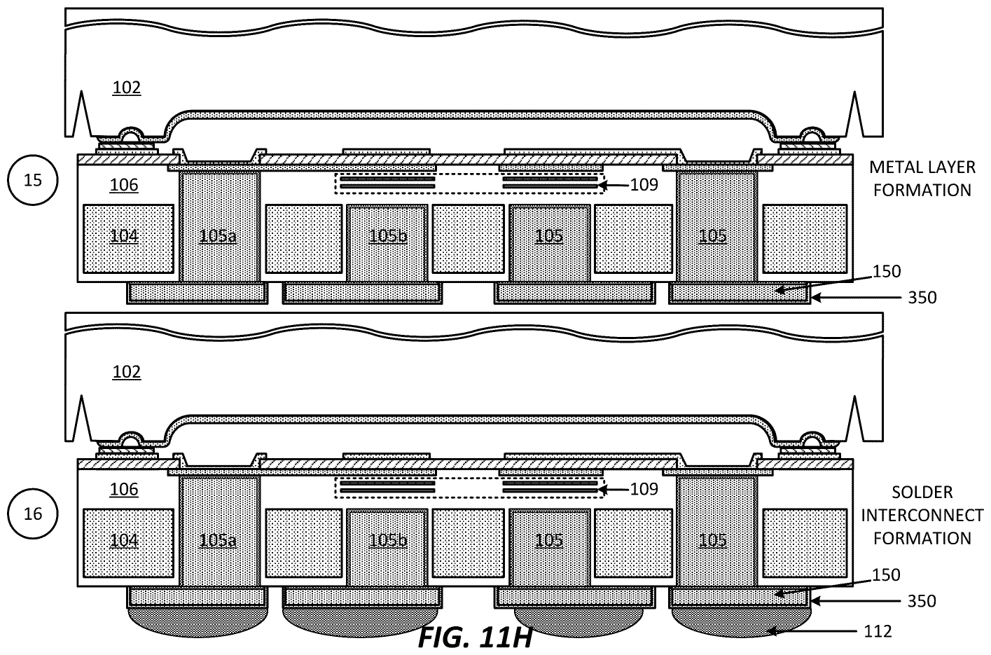

In some implementations, fabricating a device includes several processes. FIGS. 11A-11H illustrate an exemplary sequence for providing or fabricating a device comprising an acoustic layer and at least one via interconnect. In some implementations, the sequence of FIGS. 11A-11H may be used to provide or fabricate the device 1000. However, the process of FIGS. 11A-11H may be used to fabricate any of the devices described in the disclosure.

It should be noted that the sequence of FIGS. 11A-11H may combine one or more stages in order to simplify and/or clarify the sequence for providing or fabricating a device. In some implementations, the order of the processes may be changed or modified. In some implementations, one or more of processes may be replaced or substituted without departing from the scope of the disclosure.

Stage 1, as shown in FIG. 11A, illustrates a state after an acoustic layer 101 is provided. The acoustic layer 101 may include a carrier 901, a metal layer 902, at least one dielectric layer 106, at least one material layer 109, a piezoelectric layer 108, and a metal layer. An example of providing and/or fabricating an acoustic layer is shown and described below in at least FIGS. 9A-9C. The metal layer 902 may be patterned to be a plurality of interconnects 130.

Stage 2 illustrates a state after a substrate 104 and a dielectric layer 106 are provided. The substrate 104 may include a plurality of cavities 1102. An example of providing and/or fabricating a substrate is shown and described below in at least FIGS. 8A-8B.

Stage 3, as shown in FIG. 11B, illustrates a state after the acoustic layer 101 is coupled and/or bonded to the substrate 104. The bond interface 1060 may be a conceptual representation of where in the dielectric layer 106 is the acoustic layer 101 coupled to the dielectric layer 106 next to the substrate 104. The bond interface 1060 may not be present, visible nor detectable. For example, the dielectric layer 106 above the bond interface 1060 may not be separate from the dielectric layer 106 below the bond interface 1060. The dielectric layer 106 above the bond interface 1060 may be continuous and/or contiguous to the dielectric layer 106 below the bond interface 1060. Stage 4 illustrates a state after the carrier 901 is removed and/or detached from the piezoelectric layer 108.

Stage 5, as shown in FIG. 11C, illustrates a state after the piezoelectric layer 108 is patterned and a plurality of interconnects 130, the plurality of interconnects 131 and/or a metal layer 330 are formed. An exposure process and a development process may be used to pattern the piezoelectric layer 108. A sputtering, evaporation process may be used to form the plurality of interconnects 130 and/or the plurality of interconnects 131.

Stage 6, as shown in FIG. 11C, illustrates a state after the lid layer 102 is coupled and/or bonded to the acoustic layer 101. The lid layer 102 may be coupled to the plurality of interconnects 131 of the acoustic layer 101 through the metal layer 121 and/or the metal layer 330, which may provide a hermetic seal between the lid layer 102 and the acoustic layer 101. The cavity 120 is located between the lid layer 102 and the acoustic layer 101. The cavity 120 may be located between the lid layer 102 and the piezoelectric layer 108.

Stage 7, as shown in FIG. 11D, illustrates a state after portions of the substrate 104 are removed, revealing the plurality of cavities 1102. A grinding process may be used to remove portions of the substrate 104.

Stage 8, illustrates a state after a seed layer 305 is provided. A sputtering process may be used to form the seed layer 305. The seed layer 305 may be formed in the plurality of cavities 1102.

Stage 9, as shown in FIG. 11E, illustrates a state after a plurality of via interconnects 105 are formed in at least the plurality of cavities 1102. A plating process may be used to form the plurality of via interconnects 105. A pasting process may be used to form the plurality of via interconnects 105. The plurality of via interconnects 105 may be coupled to the seed layer 305. In some implementations, the seed layer 305 may be considered part of the plurality of via interconnects 105. The plurality of via interconnects 105 include via interconnects with a more uniform width across the height of the via interconnect. For example, the via interconnect 105a may have a width or diameter that is approximately uniform (e.g., approximately the same) through the entire height of the via interconnect 105a. Similarly, the via interconnect 105b may have a width or diameter that is approximately uniform (e.g., approximately the same) through the entire height of the via interconnect 105b.

Stage 10, illustrates a state after planarization of the substrate 104 and the plurality of via interconnects 105. A grinding and/or polishing process may be used to remove portions of the plurality of via interconnects 105, portions of the seed layer 305 and portions of the substrate 104.

Stage 11, as shown in FIG. 11F, illustrates a state after additional portions of the substrate 104 are removed. An etching process may be used to remove portions of the substrate 104.

Stage 12 illustrates a state after a dielectric layer 1106 is formed over a surface of the substrate 104 and the plurality of via interconnects 105. A deposition process may be used to provide the dielectric layer 1106. The dielectric layer 1106 may include a same material or a similar material as the dielectric layer 106.

Stage 13, as shown in FIG. 11G illustrates a state after planarization of a bottom portion of the dielectric layer 106 and the plurality of via interconnects 105. The dielectric layer 106 may represent the dielectric layer 106 and the dielectric layer 1106. A polishing (planarization) process may be used to remove portions of the dielectric layer 106 and portions of the via interconnects 105.

Stage 14 illustrates a state after a plurality of metallization interconnects 150 are formed and coupled to the plurality of via interconnects 105. The plurality of metallization interconnects 150 may include a seed layer. In some implementations, a deposition process, a lamination process, an etching process (e.g., photo etching process), a laser process, an exposure process, a development process, a lithography process, a plating process, and/or a strip process may be used to form the plurality of metallization interconnects 150. The plurality of metallization interconnects 150 may include a plurality of pad interconnects.

Stage 15, as shown in FIG. 11H, illustrates a state after a metal layer 350 are formed on the plurality of metallization interconnects 150. An electro or chemical plating process may be used to form the metal layer 350. The metal layer 350 may considered part of the plurality of metallization interconnects 150. In some implementations, more than one metal layer may be formed. The metal layer 350 may include a different material than a material from the plurality of metallization interconnects 150.

Stage 16 illustrates a state after a plurality of solder interconnects 112 are formed and coupled to the plurality of metallization interconnects 150 and/or the metal layer 350. A solder reflow process may be used to form the plurality of solder interconnects 112. In some implementations, the lid layer 102 may be thinned after the plurality of solder interconnects 112 are coupled to the plurality of metallization interconnects 150 and/or the metal layer 350.

Different implementations may use different processes for forming the metal layer(s) and/or interconnects. In some implementations, a chemical vapor deposition (CVD) process, a physical vapor deposition (PVD) process (sputtering, evaporation), a spray coating process, and/or a plating process may be used to form the metal layer(s).

### Exemplary Flow Diagram of a Method for Fabricating a Device Comprising an Acoustic Layer and at Least One Via Interconnect

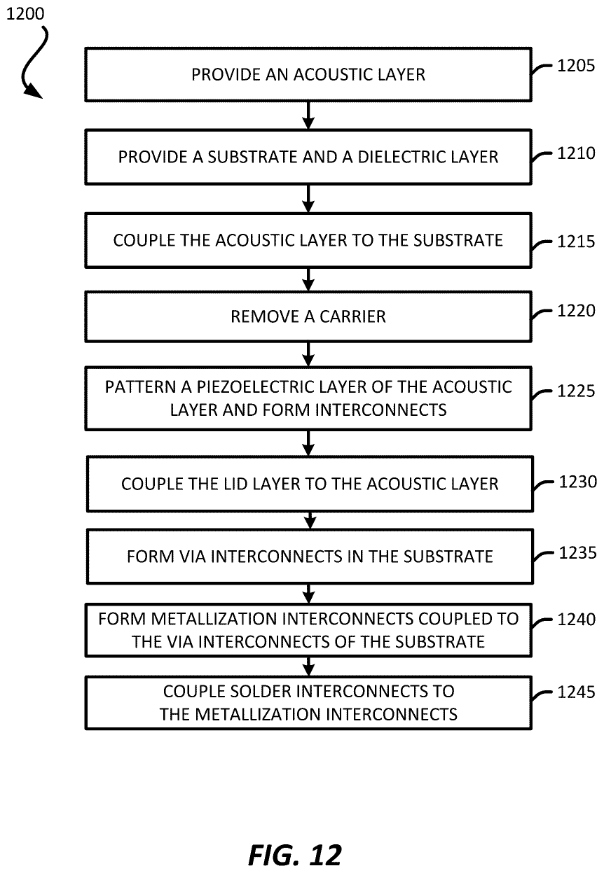

In some implementations, fabricating a device includes several processes. FIG. 12 illustrates an exemplary flow diagram of a method 1200 for providing or fabricating a device that includes an acoustic layer and at least one via interconnect. In some implementations, the method 1200 of FIG. 12 may be used to provide or fabricate the device 1000 described in the disclosure. However, the method 1200 may be used to provide or fabricate any of the devices described in the disclosure.

It should be noted that the method 1200 of FIG. 12 may combine one or more processes in order to simplify and/or clarify the method for providing or fabricating a device. In some implementations, the order of the processes may be changed or modified.

The method provides (at 1205) an acoustic layer. Stage 1 of FIG. 11A, illustrates and describes an example of a state after an acoustic layer 101 is provided. The acoustic layer 101 may include a carrier 901, a metal layer 902, at least one dielectric layer 106, at least one material layer 109, a piezoelectric layer 108, and a metal layer. An example of providing and/or fabricating an acoustic layer is shown and described below in at least FIGS. 9A-9C. The metal layer 902 may be patterned to be a plurality of interconnects 130.

The method provides (at 1210) a substrate and a dielectric layer. Stage 2 of FIG. 11A, illustrates and describes an example of a state after a substrate 104 and a dielectric layer 106 are provided. The substrate 104 may include a plurality of cavities 1102. An example of providing and/or fabricating a substrate is shown and described below in at least FIGS. 8A-8B.

The method couples (at 1215) the acoustic layer to a substrate and a dielectric layer. Stage 3 of FIG. 11B, illustrates and describes an example of a state after the acoustic layer 101 is coupled and/or bonded to the substrate 104. The bond interface 1060 may be a conceptual representation of where in the dielectric layer 106 is the acoustic layer 101 coupled to the dielectric layer 106 next to the substrate 104. The bond interface 1060 may not be present, visible nor detectable. For example, the dielectric layer 106 above the bond interface 1060 may not be separate from the dielectric layer 106 below the bond interface 1060. The dielectric layer 106 above the bond interface 1060 may be continuous and/or contiguous to the dielectric layer 106 below the bond interface 1060.

The method removes (at 1220) a carrier. Stage 4 of FIG. 11B, illustrates and describes an example of a state after the carrier 901 is removed and/or detached from the piezoelectric layer 108.

The method patterns (at 1225) a piezoelectric layer and forms interconnects. Stage 5 of FIG. 11C, illustrates and describes an example of a state after the piezoelectric layer 108 is patterned and a plurality of interconnects 130, the plurality of interconnects 131 and/or a metal layer 330 are formed. An exposure process and a development process may be used to pattern the piezoelectric layer 108. A sputtering or evaporation process may be used to form the plurality of interconnects 130 and/or the plurality of interconnects 131.

The method couples (at 1230) a lid layer to the acoustic layer. Stage 6 of FIG. 11C, illustrates and describes an example of a state after the lid layer 102 is coupled and/or bonded to the acoustic layer 101. The lid layer 102 may be coupled to the plurality of interconnects 131 of the acoustic layer 101 through the metal layer 121 and/or the metal layer 330, which may provide a hermetic seal between the lid layer 102 and the acoustic layer 101. The cavity 120 is located between the lid layer 102 and the acoustic layer 101. The cavity 120 may be located between the lid layer 102 and the piezoelectric layer 108.

The method forms (at 1235) a plurality of via interconnects in the substrate. Stage 7 of FIG. 11D through stage 13 of FIG. 11G, illustrates examples of forming a plurality of via interconnects. Stage 7 of FIG. 11D, illustrates and describes an example of a state after portions of the substrate 104 are removed, revealing the plurality of cavities 1102. A grinding process may be used to remove portions of the substrate 104.

Stage 8 of FIG. 11D, illustrates and describes an example of a state after a seed layer 305 is provided. A sputtering process may be used to form the seed layer 305. The seed layer 305 may be formed in the plurality of cavities 1102.

Stage 9 of FIG. 11E, illustrates and describes an example of a state after a plurality of via interconnects 105 are formed in at least the plurality of cavities 1102. A plating process may be used to form the plurality of via interconnects 105. A pasting process may be used to form the plurality of via interconnects 105. The plurality of via interconnects 105 may be coupled to the seed layer 305. In some implementations, the seed layer 305 may be considered part of the plurality of via interconnects 105. The plurality of via interconnects 105 include via interconnects with a more uniform width across the height of the via interconnect. For example, the via interconnect 105a may have a width or diameter that is approximately uniform (e.g., approximately the same) through the entire height of the via interconnect 105a. Similarly, the via interconnect 105b may have a width or diameter that is approximately uniform (e.g., approximately the same) through the entire height of the via interconnect 105b.

Stage 10 of FIG. 11E, illustrates and describes an example of a state after planarization of the substrate 104 and the plurality of via interconnects 105. A grinding and/or polishing process may be used to remove portions of the plurality of via interconnects 105, portions of the seed layer 305 and portions of the substrate 104.

Stage 11 of FIG. 11F, illustrates and describes an example of a state after additional portions of the substrate 104 are removed. An etching process may be used to remove portions of the substrate 104.

Stage 12 of FIG. 11F, illustrates and describes an example of a state after a dielectric layer 1106 is formed over a surface of the substrate 104 and the plurality of via interconnects 105. A deposition process may be used to provide the dielectric layer 1106. The dielectric layer 1106 may include a same material or a similar material as the dielectric layer 106.

Stage 13 of FIG. 11G, illustrates and describes an example of a state after planarization of a bottom portion of the dielectric layer 106 and the plurality of via interconnects 105. The dielectric layer 106 may represent the dielectric layer 106 and the dielectric layer 1106. A polishing process may be used to remove portions of the dielectric layer 106 and portions of the via interconnects 105.

The method forms (at 1240) a plurality of metallization interconnects that are coupled to the plurality of via interconnects. Stage 14 of FIG. 11G, illustrates and describes an example of a state after a plurality of metallization interconnects 150 are formed and coupled to the plurality of via interconnects 105. The plurality of metallization interconnects 150 may include a seed layer. In some implementations, a deposition process, a lamination process, an etching process (e.g., photo etching process), a laser process, an exposure process, a development process, a lithography process, a plating process, and/or a strip process may be used to form the plurality of metallization interconnects 150. The plurality of metallization interconnects 150 may include a plurality of pad interconnects.

Stage 15 of FIG. 11H, illustrates a state after a metal layer 350 are formed on the plurality of metallization interconnects 150. A sputtering process may be used to form the metal layer 350. The metal layer 350 may considered part of the plurality of metallization interconnects 150. In some implementations, more than one metal layer may be formed. The metal layer 350 may include a different material than a material from the plurality of metallization interconnects 150.

The method couples (at 1245) a plurality of solder interconnects to the plurality of metallization interconnects. Stage 16 of FIG. 11H, illustrates and describes an example of a state after a plurality of solder interconnects 112 are formed and coupled to the plurality of metallization interconnects 150 and/or the metal layer 350. A solder reflow process may be used to form the plurality of solder interconnects 112. In some implementations, the lid layer 102 may be thinned after the plurality of solder interconnects 112 are coupled to the plurality of metallization interconnects 150 and/or the metal layer 350.

In some implementations, the method is performed on a wafer, and the method may then singulate the wafer to fabricate individual devices. A saw process may be used to dice the wafer into individual devices comprising an acoustic layer.

Different implementations may use different processes for forming the metal layer(s) and/or interconnects. In some implementations, a chemical vapor deposition (CVD) process, a physical vapor deposition (PVD) process (sputtering, evaporation) a spray coating process, and/or a plating process may be used to form the metal layer(s).

### Exemplary Device Comprising an Acoustic Layer and at Least One Via Interconnect

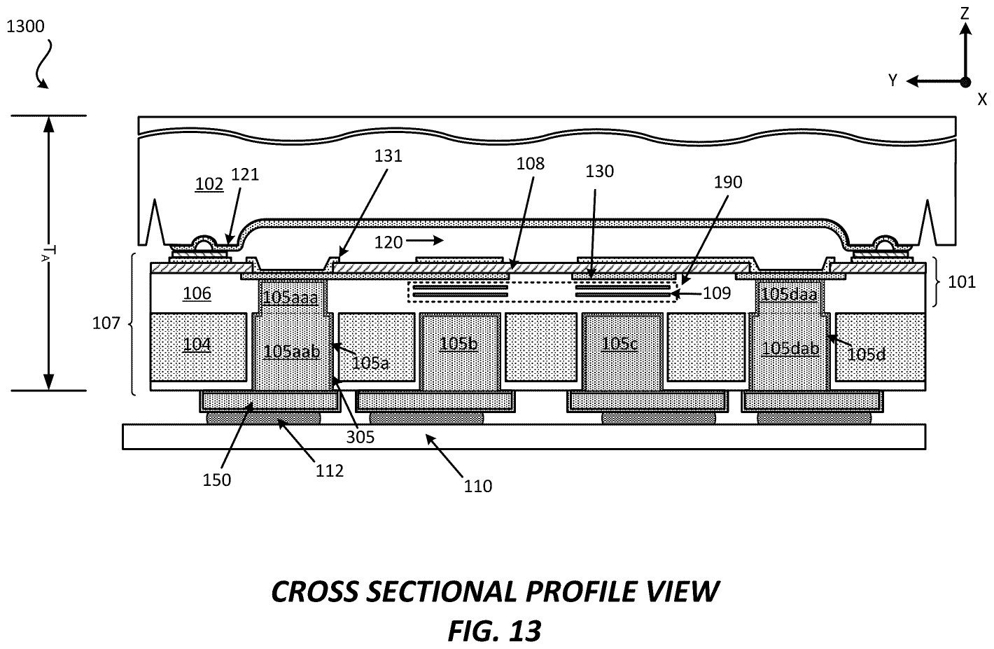

FIG. 13 illustrates a cross sectional profile view of a device 1300 that includes an acoustic layer and at least one via interconnect. The device 1300 may be similar to the device 100 of FIG. 1, the device 200 of FIG. 2, the device 300 of FIG. 3, the device 400 of FIG. 4 and/or the device 1000 of FIG. 10, and may include similar and/or the same components as described for the device 100, the device 200, the device 300, the device 400 and/or the device 1000. The device 1300 includes a plurality of via interconnects 105 with a different design and/or configurations.

The device 1300 may include a plurality of via interconnects 105 with a different design from the device 100, the device 200, the device 300, the device 400 and/or the device 1000. The plurality of via interconnects 105 include via interconnects with two portions with different widths. The via interconnect 105a includes a via interconnect 105aaa and a via interconnect 105aab. The via interconnect 105aaa may be a first via interconnect portion of the via interconnect 105a. The via interconnect 105aaa has a first width. The via interconnect 105aab may be a second via interconnect portion of the via interconnect 105a. The via interconnect 105aab has a second width. The second width may be greater than the first width. The via interconnect 105d includes a via interconnect 105daa and a via interconnect 105dab. The via interconnect 105daa may be a first via interconnect portion of the via interconnect 105d. The via interconnect 105daa has a first width. The via interconnect 105dab may be a second via interconnect portion of the via interconnect 105d. The via interconnect 105dab has a second width. The second width may be greater than the first width. The sequence and/or the process of FIGS. 11A-11H may be used to fabricate the device 1300.

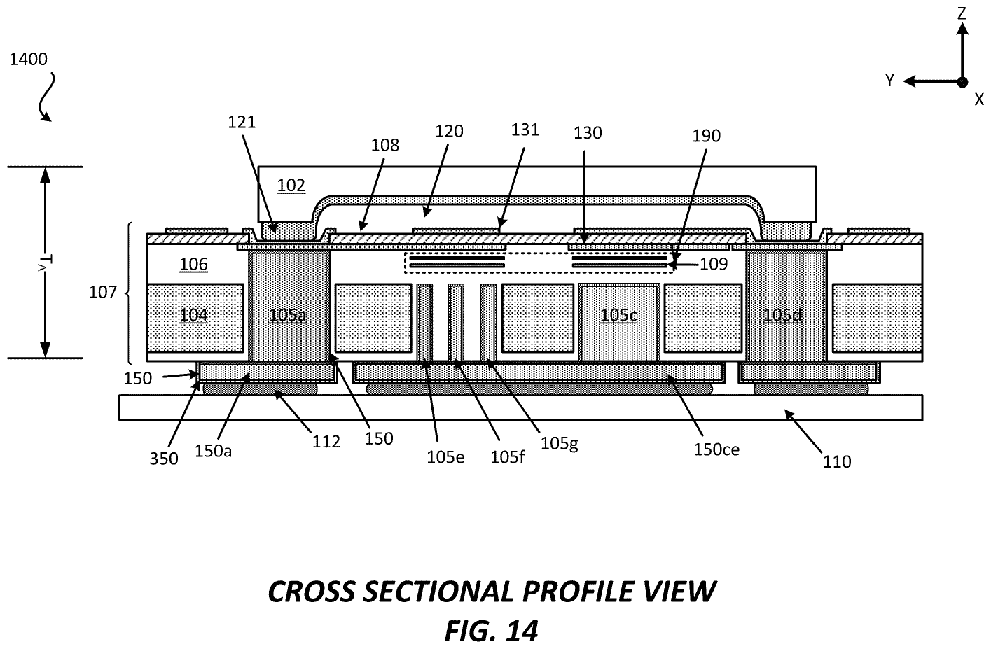

FIG. 14 illustrates a cross sectional profile view of a device 1400 that includes an acoustic layer, an acoustic mirror portion and at least one via interconnect. The device 1400 may be similar to the device 100 of FIG. 1, the device 200 of FIG. 2, the device 300 of FIG. 3, the device 400 of FIG. 4 and/or the device 1000 of FIG. 10, and may include similar and/or the same components as described for the device 100, the device 200, the device 300, the device 400 and/or the device 1000. The device 1400 includes a plurality of via interconnects 105 with a different design and/or configurations. The lid layer 102 is coupled to the device base 107 through the metal layer 121. The metal layer 121 may touch at least one interconnect from the plurality of interconnects 130 and/or he plurality of interconnects 131. The portion of the metal layer 121 that touches the at least one interconnect from the plurality of interconnects 130 and/or he plurality of interconnects 131 may vertically overlap with a via interconnect from the plurality of via interconnects 105. The metal layer 121 may be configured as a shield (e.g., electromagnetic interference shield).

The plurality of via interconnects 105 may include a via interconnect 105a, a via interconnect 105c, a via interconnect 105d, a via interconnect 105e, a via interconnect 105f and a via interconnect 105g. The via interconnect 105e, the via interconnect 105f and/or the via interconnect 105g may be either configured or designed as via interconnect arrays with a different width (or diameter) or as via interconnects with a larger width of the via interconnect 105c (either or). Different implementations may have different combinations of via interconnects with different widths and/or diameters. The via interconnect 105e, the via interconnect 105f, the via interconnect 105g and/or the via interconnect 105c may be coupled to the metallization interconnects 150ce.

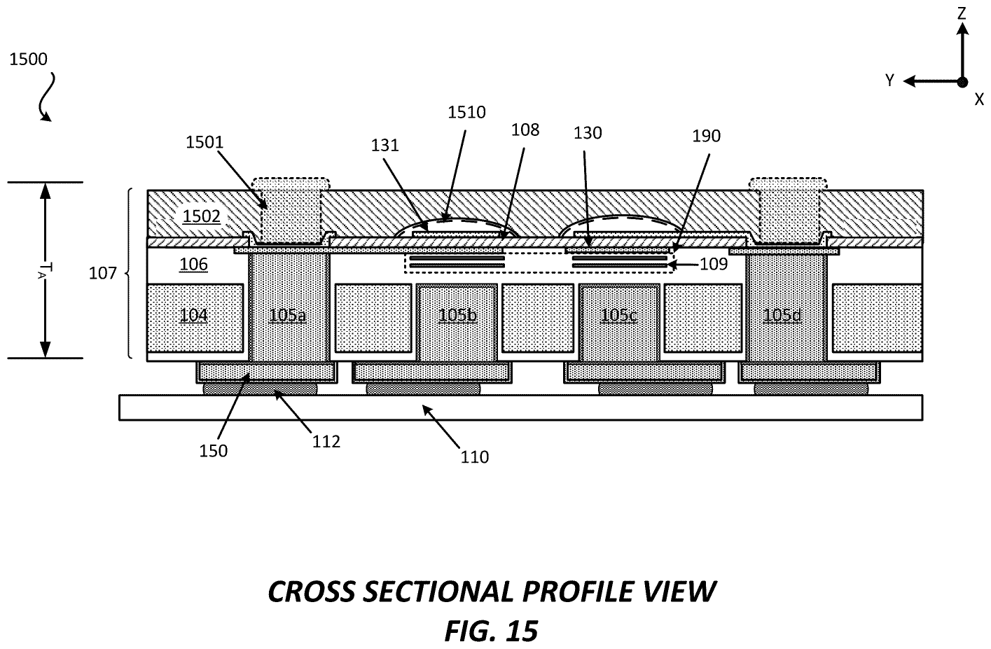

FIG. 15 illustrates a cross sectional profile view of a device 1500 that includes an acoustic layer and at least one via interconnect. The device 1500 may be similar to the device 100 of FIG. 1, the device 200 of FIG. 2, the device 300 of FIG. 3, the device 400 of FIG. 4, the device 1000 of FIG. 10, the device 1300 of FIG. 13 and/or the device 1400 of FIG. 14, and may include similar and/or the same components as described for the device 100, the device 200, the device 300, the device 400, the device 1000, the device 1300 and/or the device 1400. The device 1500 includes a lid layer with a different design and/or configuration.

The device 1500 includes a lid layer 1502, a cavity 1510 and a plurality of lid interconnects 1501. The lid layer 1502 may include a polymer. The plurality of lid interconnects 1501 may include lid via interconnects and/or lid pad interconnects. The plurality of lid interconnects 1501 may extend through the lid layer 1502. The plurality of lid interconnects 1501 may be coupled to the plurality of interconnects 130, the plurality of interconnects 131, and/or the plurality of via interconnects 105. The cavity 1510 may be located in the lid layer 1502. The cavity 1510 may be one of several cavities in the lid layer 1502. The cavity 1510 may be located over the piezoelectric layer 108. The cavity 1510 may be located in the lid layer 1502 and the device base 107. The lid layer 1502 may be coupled to and touch the piezoelectric layer 108.

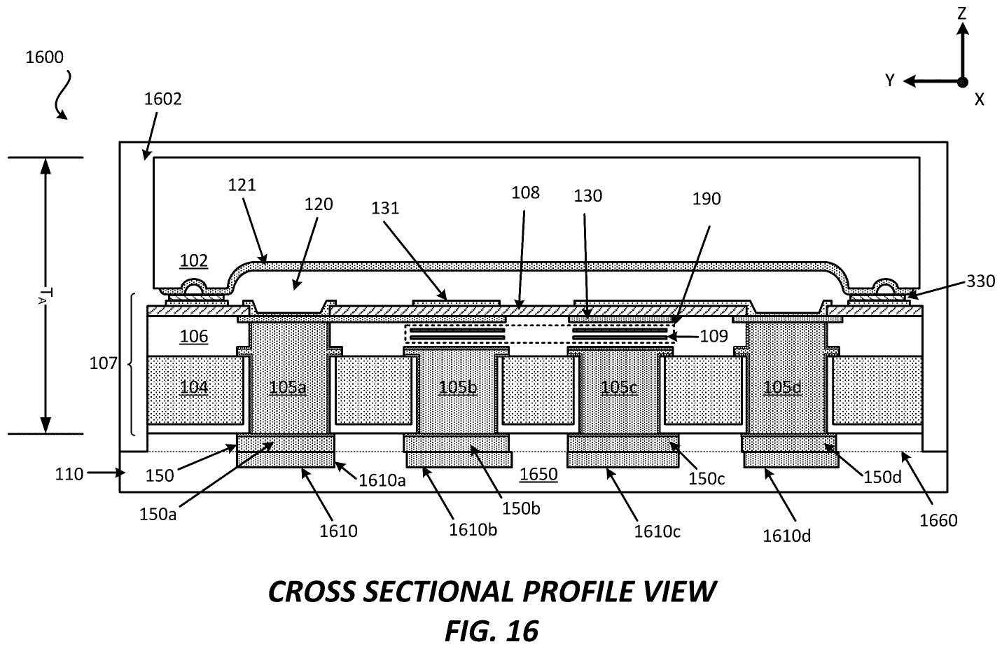

FIG. 16 illustrates a cross sectional profile view of a device 1600 that includes an acoustic layer and at least one via interconnect. The device 1600 may be similar to the device 100 of FIG. 1, the device 200 of FIG. 2, the device 300 of FIG. 3, the device 400 of FIG. 4, the device 1000 of FIG. 10, the device 1300 of FIG. 13 and/or the device 1400 of FIG. 14, and may include similar and/or the same components as described for the device 100, the device 200, the device 300, the device 400, the device 1000, the device 1300 and/or the device 1400.

The device 1600 includes a lid layer 102, the device base 107, the substrate 110 and an encapsulation layer 1602. The substrate 110 includes a plurality of interconnects 1610. The device base 107 is coupled to the substrate 110 through the plurality of metallization interconnects 150 and the plurality of interconnects 1610. The plurality of metallization interconnects 150 are coupled to the plurality of interconnects 1610 through hybrid bonding. The encapsulation layer 1602 may at least partially encapsulate the device base 107 and the lid layer 102. The encapsulation layer 1602 may include a mold, a resin, an epoxy and/or a filler. The encapsulation layer 1602 may be provided by using a compression and transfer molding process, a sheet molding process, or a liquid molding process. The encapsulation layer 1602 may be coupled to the substrate 110. The substrate 110 may include a dielectric layer 1650. The dielectric layer 1650 may be coupled to the dielectric layer 106. The dielectric layer 106 may not be distinguishable from the dielectric layer 1650. The dielectric layer 1650 may include the same material or a similar material as the dielectric layer 106.

FIG. 16 illustrates a bond interface 1660 may be a conceptual representation of where different portions of the dielectric layer 106 may be coupled to the dielectric layer 1650. The bond interface 1660 may not be present, visible nor detectable. For example, the dielectric layer 106 above the bond interface 1660 may not be separate from the dielectric layer 1650 below the bond interface 260. The dielectric layer 106 above the bond interface 1660 may be continuous and/or contiguous to the dielectric layer 1650 below the bond interface 1660. In some implementations, the plurality of metallization interconnects 150 may be coupled to the plurality of interconnects 1610 through hybrid bonding. The metallization interconnect 150a may be coupled to the interconnect 1610a. The metallization interconnect 150b may be coupled to the interconnect 1610b. The metallization interconnect 150b may partially overlap with the interconnect 1610b. The metallization interconnect 150c may be coupled to the interconnect 1610c. The metallization interconnect 150d may be coupled to the interconnect 1610d. The metallization interconnect 150d may partially overlap with the interconnect 1610d.

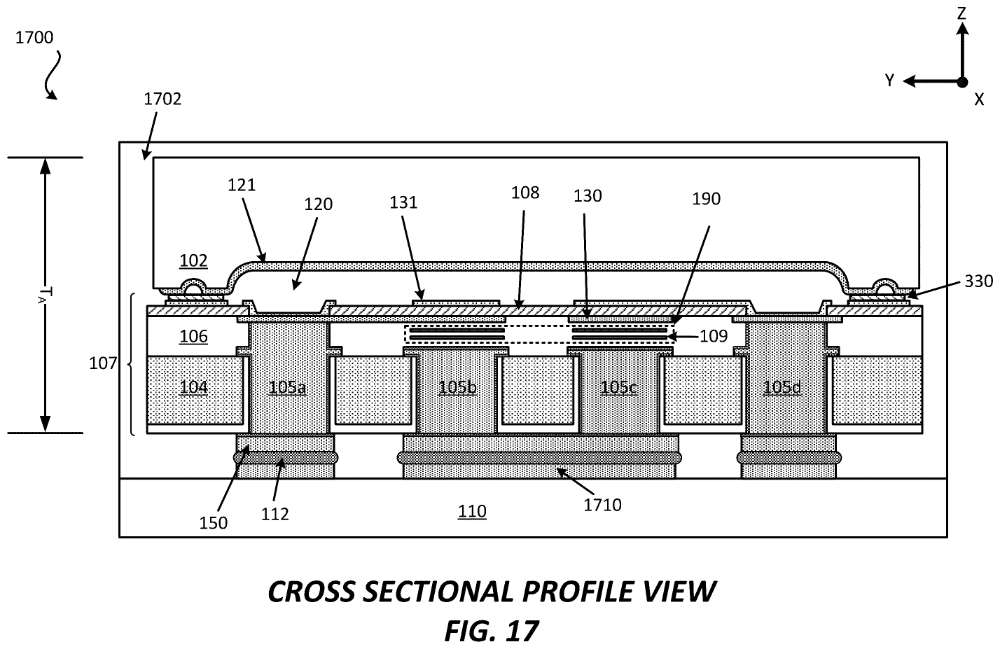

FIG. 17 illustrates a cross sectional profile view of a device 1700 that includes an acoustic layer and at least one via interconnect. The device 1700 may be similar to the device 100 of FIG. 1, the device 200 of FIG. 2, the device 300 of FIG. 3, the device 400 of FIG. 4, the device 1000 of FIG. 10, the device 1300 of FIG. 13 and/or the device 1400 of FIG. 14, and may include similar and/or the same components as described for the device 100, the device 200, the device 300, the device 400, the device 1000, the device 1300 and/or the device 1400.

The device 1700 includes a lid layer 102, the device base 107, the substrate 110 and an encapsulation layer 1702. The substrate 110 includes a plurality of interconnects 1610. The device base 107 is coupled to the substrate 110 through the plurality of metallization interconnects 150, the plurality of solder interconnects 112 and the plurality of interconnects 1710. The plurality of metallization interconnects 150 are coupled to the plurality of interconnects 1710 through the plurality of solder interconnects 112. The encapsulation layer 1702 may at least partially encapsulate the device base 107 and the lid layer 102. The encapsulation layer 1702 may include a mold, a resin, an epoxy and/or a filler. The encapsulation layer 1702 may be provided by using a compression and transfer molding process, a sheet molding process, or a liquid molding process. The encapsulation layer 1702 may be coupled to a surface of the substrate 110.

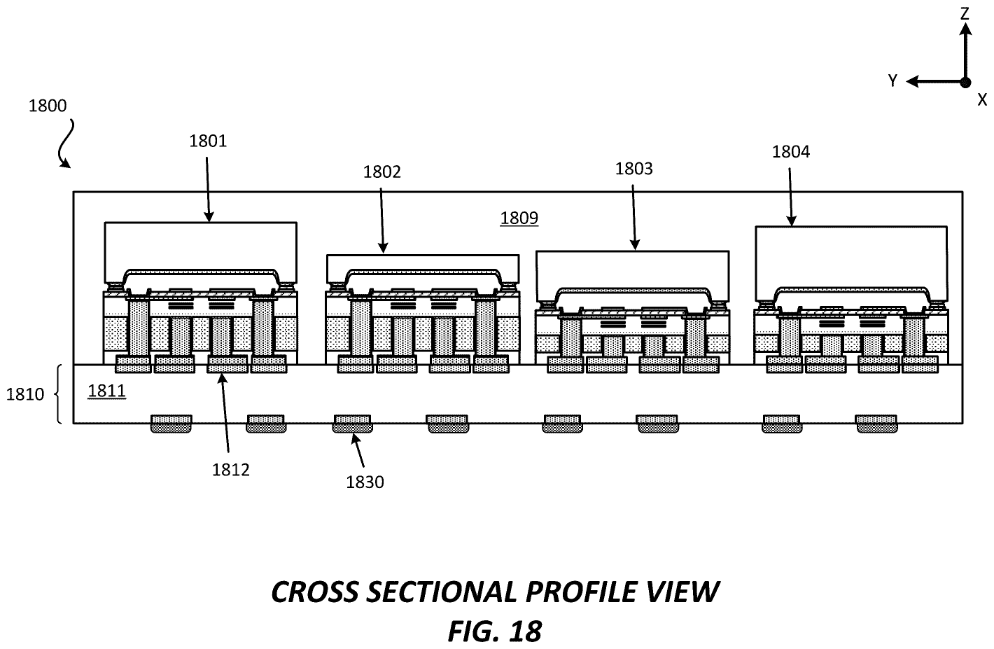

In some implementations, a package may include several devices with acoustic devices. FIG. 18 illustrates a package 1800 that includes several devices with an acoustic layer. The package 1800 may be configured as an acoustic filter. The package 1800 includes a first device 1801, a second device 1802, a third device 1803, a fourth device 1804, a substrate 1810, and an encapsulation layer 1809. The substrate 1810 may be an interposer. The substrate 1810 may be a laminated substrate. The substrate 1810 may include at least one dielectric layer 1811 and a plurality of interconnects 1812. The first device 1801, the second device 1802, the third device 1803 and/or the fourth device 1804 may be any of the devices with an acoustic layer described in the disclosure.

The first device 1801, the second device 1802, the third device 1803 and the fourth device 1804 may be coupled to the substrate 1810 through hybrid bonding. The first device 1801, the second device 1802, the third device 1803 and/or the fourth device 1804 may each be configured to operate as separate acoustic wave resonators for different frequencies.

The encapsulation layer 1809 may be coupled to a surface of the substrate 1810. The encapsulation layer 1809 may at least partially encapsulate the first device 1801, the second device 1802, the third device 1803 and/or the fourth device 1804. The encapsulation layer 1809 may include a mold, a resin, an epoxy and/or a filler. The encapsulation layer 1809 may be provided by using a compression and transfer molding process, a sheet molding process, or a liquid molding process.

As mentioned above, the different devices may have different configurations. As shown in FIG. 18, the first device 1801 has a thicker lid layer than the lid layer of the second device 1802. The substrate of the third device 1803 is thinner than the thickness of the substrate of the second device 1802. The lid layer of the fourth device 1804 is thicker than the lid layer of the third device 1803. The package 1800 illustrates one example of a package with different device with an acoustic layer. However, different packages may have different number of devices with an acoustic layer with different acoustic devices with different configurations and/or designs.

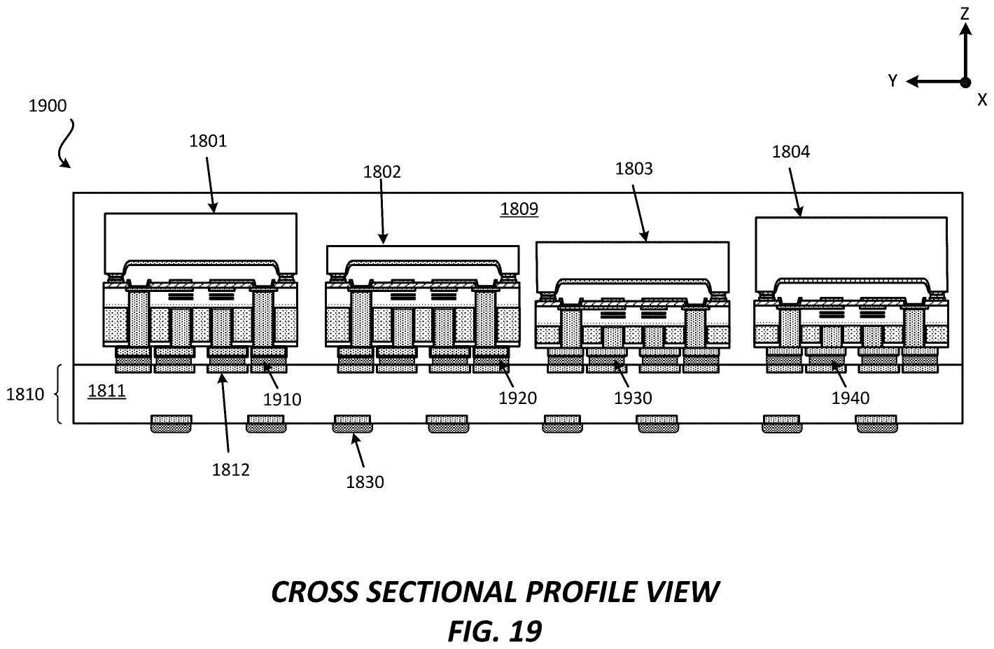

FIG. 19 illustrates a package 1900 that includes several devices with an acoustic layer. The package 1900 may be configured as an acoustic filter. The package 1900 is similar to the package 1800. However, the devices of the package 1900 are coupled to the substrate 1810 through solder interconnects instead of through hybrid bonding. The package 1900 includes a first device 1801, a second device 1802, a third device 1803, a fourth device 1804, a substrate 1810, and an encapsulation layer 1809. The substrate 1810 may be an interposer. The substrate 1810 may be a laminated substrate. The substrate 1810 may include at least one dielectric layer 1811 and a plurality of interconnects 1812. The first device 1801, the second device 1802, the third device 1803 and/or the fourth device 1804 may be any of the devices with an acoustic layer described in the disclosure.

The first device 1801 may be coupled to the plurality of interconnects 1812 of the substrate 1810 through a first plurality of solder interconnects 1910. The second device 1802 may be coupled to the plurality of interconnects 1812 of the substrate 1810 through a second plurality of solder interconnects 1920. The third device 1803 may be coupled to the plurality of interconnects 1812 of the substrate 1810 through a third plurality of solder interconnects 1930. The fourth device 1804 may be coupled to the plurality of interconnects 1812 of the substrate 1810 through a fourth plurality of solder interconnects 1940.

The encapsulation layer 1809 may be coupled to a surface of the substrate 1810. The encapsulation layer 1809 may at least partially encapsulate the first device 1801, the second device 1802, the third device 1803 and/or the fourth device 1804. The encapsulation layer 1809 may include a mold, a resin, an epoxy and/or a filler. The encapsulation layer 1809 may be provided by using a compression and transfer molding process, a sheet molding process, or a liquid molding process.

### Exemplary Electronic Devices

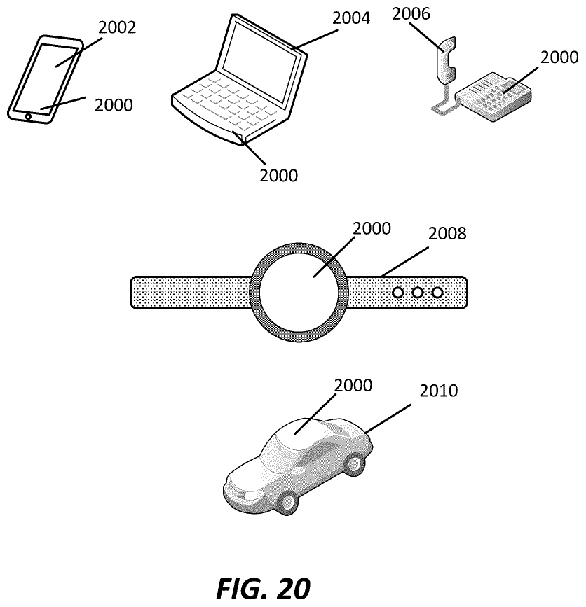

FIG. 20 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 2002, a laptop computer device 2004, a fixed location terminal device 2006, a wearable device 2008, or automotive vehicle 2010 may include a device 2000 as described herein. The device 2000 may be, for example, any of the devices and/or integrated circuit (IC) packages described herein. The devices 2002, 2004, 2006 and 2008 and the vehicle 2010 illustrated in FIG. 20 are merely exemplary. Other electronic devices may also feature the device 2000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-4, 5A-5H, 6, 7A-7C, 8A-8D, 9A-9D, 10, 11A-11H, and 12-20 may be rearranged and/or combined into a single component, process, feature or function or embodied in several components, processes, or functions. Additional elements, components, processes, and/or functions may also be added without departing from the disclosure. It should also be noted FIGS. 1-4, 5A-5H, 6, 7A-7C, 8A-8D, 9A-9D, 10, 11A-11H, and 12-20 and its corresponding description in the present disclosure is not limited to dies and/or ICs. In some implementations, FIGS. 1-4, 5A-5H, 6, 7A-7C, 8A-8D, 9A-9D, 10, 11A-11H, and 12-20 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration. ” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process (sputtering, evaporation), a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A device comprising a lid layer; an acoustic layer coupled to the lid layer, wherein the acoustic layer comprises: a piezoelectric layer; a dielectric layer; at least one material layer located in the dielectric layer; and a plurality of interconnects coupled to the piezoelectric layer; a cavity located between the lid layer and the piezoelectric layer; a substrate coupled to the dielectric layer of the acoustic layer; and at least one via interconnect coupled to the piezoelectric layer through the plurality of interconnects, wherein the at least one via interconnect extends through the dielectric layer and the substrate.

Aspect 2: The device of aspect 1, wherein the dielectric layer comprises a first acoustic impedance, and wherein the at least one material layer comprises a second acoustic impedance that is different from the first acoustic impedance.

Aspect 3: The device of aspects 1 through 2, wherein at least part of the dielectric layer and the at least one material layer are configured as an acoustic mirror.

Aspect 4: The device of aspects 1 through 3, wherein the at least one via interconnect is configured to provide an electrical path through the dielectric layer and the substrate.

Aspect 5: The device of aspects 1 through 4, wherein the lid layer further comprises a lid via interconnect that extends through the lid layer.

Aspect 6: The device of aspect 5, wherein the lid via interconnect is coupled to the plurality of interconnects of the acoustic layer.

Aspect 7: The device of aspects 1 through 6, further comprising a plurality of metallization interconnects coupled to the at least one via interconnect.

Aspect 8: The device of aspects 1 through 7, wherein the at least one via interconnect comprises: a first via interconnect that extends through the dielectric layer; a pad coupled to the first via interconnect; and a second via interconnect that extends through the substrate, wherein the second via interconnect is coupled to the pad.

Aspect 9: The device of aspects 1 through 8, wherein the lid layer is coupled to the acoustic layer such that a hermetic seal is provided between the lid layer and the acoustic layer.

Aspect 10: The device of aspects 1 through 9, wherein the lid layer comprises silicon, glass, fused silica, ceramic, polymer, or a combination thereof.

Aspect 11: The device of aspects 1 through 10, wherein the device includes an acoustic wave device.

Aspect 12: The device of aspects 1 through 11, further comprising at least one thermal via interconnect extending through the substrate, wherein the at least one thermal via interconnect is free of any electrical connection with the piezoelectric layer.

Aspect 13: The device of aspects 1 through 12, wherein the plurality of interconnects are configured as electrodes.

Aspect 14: The device of aspects 1 through 13, wherein the at least one material layer includes tungsten.

Aspect 15: The device of aspects 1 through 14, wherein the piezoelectric layer includes aluminum nitride (Aln) or aluminum scandium nitride (AlScN).

Aspect 16: A method for fabricating an acoustic device. The method provides a lid layer. The method couples an acoustic layer to the lid layer. The acoustic layer comprises a piezoelectric layer; a dielectric layer; at least one material layer located in the dielectric layer; and a plurality of interconnects coupled to the piezoelectric layer, wherein the acoustic layer is coupled to the lid layer such that a cavity is located between the lid layer and the piezoelectric layer. The method couples a substrate to the dielectric layer of the acoustic layer. The method forms at least one via interconnect that is coupled to the piezoelectric layer through the plurality of interconnects, wherein the at least one via interconnect extends through the dielectric layer and the substrate.

Aspect 17: The method of aspect 16, wherein the dielectric layer comprises a first acoustic impedance, and wherein the at least one material layer comprises a second acoustic impedance that is different from the first acoustic impedance.

Aspect 18: The method of aspects 16 through 17, wherein at least part of the dielectric layer and the at least one material layer are configured as an acoustic mirror.

Aspect 19: The method of aspects 16 through 18, wherein the at least one via interconnect is configured to provide an electrical path through the dielectric layer and the substrate.

Aspect 20: The method of aspects 16 through 19, wherein the at least one via interconnects comprises: a first via interconnect that extends through the dielectric layer; a pad coupled to the first via interconnect; and a second via interconnect that extends through the substrate, wherein the second via interconnect is coupled to the pad.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a lid layer;
an acoustic layer coupled to the lid layer, wherein the acoustic layer comprises:
a piezoelectric layer;
a dielectric layer;
at least one material layer located in the dielectric layer; and
a plurality of interconnects coupled to the piezoelectric layer;
a cavity located between the lid layer and the piezoelectric layer;
a substrate coupled to the dielectric layer of the acoustic layer; and
at least one via interconnect coupled to the piezoelectric layer through the plurality of interconnects, wherein the at least one via interconnect extends through the dielectric layer and the substrate.

2. The device of claim 1,
wherein the dielectric layer comprises a first acoustic impedance, and
wherein the at least one material layer comprises a second acoustic impedance that is different from the first acoustic impedance.

3. The device of claim 1, wherein at least part of the dielectric layer and the at least one material layer are configured as an acoustic mirror.

4. The device of claim 1, wherein the at least one via interconnect is configured to provide an electrical path through the dielectric layer and the substrate.

5. The device of claim 1, wherein the lid layer further comprises a lid via interconnect that extends through the lid layer.

6. The device of claim 5, wherein the lid via interconnect is coupled to the plurality of interconnects of the acoustic layer.

7. The device of claim 1, further comprising a plurality of metallization interconnects coupled to the at least one via interconnect.

8. The device of claim 1, wherein the at least one via interconnect comprises:
a first via interconnect that extends through the dielectric layer;
a pad coupled to the first via interconnect; and
a second via interconnect that extends through the substrate, wherein the second via interconnect is coupled to the pad.

9. The device of claim 1, wherein the lid layer is coupled to the acoustic layer such that a hermetic seal is provided between the lid layer and the acoustic layer.

10. The device of claim 1, wherein the lid layer comprises silicon, glass, fused silica, ceramic, polymer, or a combination thereof.

11. The device of claim 1, wherein the device includes an acoustic wave device.

12. The device of claim 1, further comprising at least one thermal via interconnect extending through the substrate, wherein the at least one thermal via interconnect is free of any electrical connection with the piezoelectric layer.

13. The device of claim 1, wherein the plurality of interconnects are configured as electrodes.

14. The device of claim 1, wherein the at least one material layer includes tungsten.

15. The device of claim 1, wherein the piezoelectric layer includes aluminum nitride (Aln) or aluminum scandium nitride (AlScN).

16. A method for fabricating an acoustic device, comprising:
providing a lid layer;
coupling an acoustic layer to the lid layer, wherein the acoustic layer comprises:
a piezoelectric layer;
a dielectric layer;
at least one material layer located in the dielectric layer; and
a plurality of interconnects coupled to the piezoelectric layer,
wherein the acoustic layer is coupled to the lid layer such that a cavity is located between the lid layer and the piezoelectric layer;
coupling a substrate to the dielectric layer of the acoustic layer; and
forming at least one via interconnect that is coupled to the piezoelectric layer through the plurality of interconnects, wherein the at least one via interconnect extends through the dielectric layer and the substrate.

17. The method of claim 16,
wherein the dielectric layer comprises a first acoustic impedance, and
wherein the at least one material layer comprises a second acoustic impedance that is different from the first acoustic impedance.

18. The method of claim 16, wherein at least part of the dielectric layer and the at least one material layer are configured as an acoustic mirror.

19. The method of claim 16, wherein the at least one via interconnect is configured to provide an electrical path through the dielectric layer and the substrate.

20. The method of claim 16, wherein the at least one via interconnects comprises:
a first via interconnect that extends through the dielectric layer;
a pad coupled to the first via interconnect; and
a second via interconnect that extends through the substrate, wherein the second via interconnect is coupled to the pad.
